(19) United States
(12) Patent Application Publication
(10) Pub. No.: US 2024/0242420 A1
(43) Pub. Date: Jul. 18, 2024

(54) INFORMATION PROCESSING APPARATUS AND NON-TRANSITORY COMPUTER READABLE MEDIUM

(71) Applicant: FUJIFILM Business Innovation Corp., Tokyo (JP)

(72) Inventors: Junichi MATSUNOSHITA, Kanagawa (JP); Tomonari TAKAHASHI, Kanagawa (JP); Yuzuru SUZUKI, Kanagawa (JP); Atsushi OGIHARA, Kanagawa (JP); Yasuyuki TANAKA, Kanagawa (JP); Yumi SEKIGUCHI, Kanagawa (JP); Ryosuke HIGASHIKATA, Kanagawa (JP)

(73) Assignee: FUJIFILM Business Innovation Corp., Tokyo (JP)

(21) Appl. No.: 18/495,103

(22) Filed: Oct. 26, 2023

(30) Foreign Application Priority Data
Jan. 18, 2023 (JP) 2023-006201

(51) Int. Cl. G06T 15/10; G06F 30/10; G06T 19/20

(52) U.S. Cl. CPC G06T 15/10; G06F 30/10; G06T 19/20; G06T 2210/32; G06T 2219/2016; G06T 2219/2021

(57) ABSTRACT

An information processing apparatus includes a processor configured to: generate multiple two-dimensional (2D) projection images from three-dimensional (3D) model data that displays product manufacturing information about a shape of a product, the 2D projection images obtained through projection of the product in multiple directions; and generate 2D drawing data where the 2D projection images are placed, in a manner that satisfies a preset layout rule, on multiple sheet regions of a number and of a sheet size determined in accordance with the preset layout rule.

### CROSS-REFERENCE TO RELATED APPLICATIONS

This application is based on and claims priority under 35 USC 119 from Japanese Patent Application No. 2023-006201 filed Jan. 18, 2023.

### BACKGROUND

### (i) Technical Field

The present disclosure relates to an information processing apparatus and a non-transitory computer readable medium.

### (ii) Related Art

Japanese Patent No. 3038521 discloses a product drawing generation apparatus. The product drawing generation apparatus stores feature type data identifying three-dimensional (3D) model data of a product and a feature type of the 3D model data, sets a projection direction to a 3D model of the product, categorizes, according to the feature type and projection direction, drawing rule data including a drawing procedure used to produce 2D data from the 3D model data, stores the categorized drawing rule data, selects a drawing rule in accordance with data indicating the projection direction and the feature type data corresponding to the 3D model data, and generates 2D data, including 2D characters and drawings, in accordance with the procedure of the selected drawing rule.

Japanese Patent No. 3744243 discloses a 2D drawing generation method. The 2D drawing generation method produces a cubic model including a 3D model from 3D model data, detects from the generated cubic model a surface having a maximum area, and extracts as a front view candidate a drawing that results from viewing the 3D model in a direction looking to the surface. The 2D drawing generation method thus generate the 2D drawing.

Japanese Unexamined Patent Application Publication No. 2007-148568 discloses an information processing apparatus. The information processing apparatus sets 2D projection images produced based on a 3D model, groups the set 2D projection images, associates the grouped 2D projection images, and outputs the grouped 2D projection images in a layout form. The information processing apparatus may thus efficiently generate standard six drawings and the like.

In 3D computer-aided design (CAD), 3D model data includes, as product manufacturing information (PMI), not only shape information indicating a component or a finished product (hereinafter referred to as a product) but also specification information, indicating reference dimensions and tolerance. In this way, when a 3D model is displayed, the PMI may be displayed as 3D annotation on the 3D model. Information on the reference dimensions and tolerance may thus be recognized without a 2D drawing.

2D drawing data may be generated from the 3D model data and a 2D drawing may thus be printed on a paper sheet for use. For example, in a manufacturing floor where no personal computers are available, a 2D drawing printed on the paper sheet may be used.

If the 2D drawing data is produced from the 3D model representing the shape of a product, multiple 2D projection views resulting from projection of the product in multiple directions may be used. The 2D projection views may be placed on paper sheets having sheet sizes corresponding thereto. If the multiple 2D projection views are placed as 2D drawings, there are a variety of factors of drawings and a condition that is to be visibly recognized by a user using the drawings. Typically, if the 2D drawing data is generated from the 3D model, the user generating the drawings may specify the layout of each 2D projection view in view of the factors of the drawings and the condition while generating the 2D drawing data from the 3D model.

In particular, when the 2D projection views are difficult to place on a single paper sheet region, the user may generate the 2D drawing data in view of which 2D projection view to place on which page and in view of how many paper sheet regions the 2D projection views are to be placed on.

### SUMMARY

Aspects of non-limiting embodiments of the present disclosure relate to providing an information processing apparatus and a non-transitory computer readable medium producing the 2D drawing data satisfying the factors of the drawings and the condition in a manner that sets the user free from an operation of specifying the layout of the 2D projection views when the 2D drawing data including the 2D projection views obtained through the projection of a product in multiple directions is produced from the 3D model data representing the shape of the product.

Aspects of certain non-limiting embodiments of the present disclosure address the above advantages and/or other advantages not described above. However, aspects of the non-limiting embodiments are not required to address the advantages described above, and aspects of the non-limiting embodiments of the present disclosure may not address advantages described above.

According to an aspect of the present disclosure, there is provided an information processing apparatus including a processor configured to: generate multiple two-dimensional (2D) projection images from three-dimensional (3D) model data that displays product manufacturing information about a shape of a product, the 2D projection images obtained through projection of the product in multiple directions; and generate 2D drawing data where the 2D projection images are placed, in a manner that satisfies a preset layout rule, on multiple regions of a number and of a sheet size determined in accordance with the preset layout rule.

### BRIEF DESCRIPTION OF THE DRAWINGS

Exemplary embodiment of the present disclosure will be described in detail based on the following figures, wherein:

FIG. 1 illustrates a system configuration of a drawing data processing system of an exemplary embodiment of the disclosure;

FIG. 2 illustrates an example of 3D model data including product manufacturing information (PMI);

FIG. 3 illustrates an example of 2D drawing data including the PMI;

FIG. 4 is a block diagram illustrating a hardware configuration of a terminal apparatus of the exemplary embodiment of the disclosure;

FIG. 5 is a functional block diagram illustrating the terminal apparatus of the exemplary embodiment of the disclosure;

FIG. 6 illustrates how a 2D drawing generator converts the 3D model data into a 2D drawing;

FIG. 7 is a flowchart illustrating an operation of the 2D drawing generator that generates 2D drawing data from the 3D model data and outputs the 2D drawing data;

FIG. 8 is a flowchart illustrating a detailed placement operation of a view on a first sheet described with reference to a step in the flowchart in FIG. 7;

FIG. 9 illustrates an example of a 2D drawing where a view including a datum is placed on a first sheet;

FIG. 10 is a flowchart illustrating an operation of the 2D drawing generator when prioritizing a layout rule to use a specified sheet size is selected;

FIG. 11 is a flowchart illustrating an operation of the 2D drawing generator when prioritizing a view count to be placed on the first page is selected;

FIG. 12 is a flowchart illustrating an operation of the 2D drawing generator when prioritizing a scaling factor is selected;

FIGS. 13A and 13B illustrate how the 2D drawing generator enlarges a view and places the enlarged view on the 2D drawing;

FIGS. 14A and 14B illustrate how the 2D drawing generator enlarges a view and places the enlarged view on the 2D drawing;

FIGS. 15A and 15B illustrate how the 2D drawing generator generates a detailed view with a portion of the view in the 2D drawing enlarged and places the detailed view on a sheet region;

FIGS. 16A and 16B illustrate how the 2D drawing generator generates a detailed view with a portion of the view in the 2D drawing enlarged and places the detailed view on the sheet region;

FIG. 17 is a flowchart illustrating a first addition method of the detailed view;

FIG. 18 is a flowchart illustrating a second addition method of the detailed view;

FIG. 19 illustrates detection criteria of a location involving using the detailed view;

FIG. 20 illustrates how the sheet region is divided into multiple regions and multiple views are respectively placed on the regions;

FIG. 21 illustrates a case in which two 2D drawing views are placed on one sheet;

FIG. 22 illustrates a case in which two 2D drawing views are placed on one sheet;

FIG. 23 illustrates an example of a labeling operation when views are free from touching;

FIG. 24 illustrates an example of a labeling operation when views are in touch with each other;

FIGS. 25A and 25B illustrate a correction method that eliminates the touching of views by performing a layout correction;

FIG. 26 illustrates a touch determination between a view drawing and a drawing frame;

FIG. 27 illustrates a touch determination between a view drawing and a drawing frame;

FIGS. 28A and 28B illustrate a correction method that eliminates the touching between the view drawing and the drawing frame by performing the layout correction;

FIG. 29 illustrates a correction example in which datum shortening is performed when touching occurs between view drawings;

FIG. 30 illustrates a correction example in which datum shortening is performed when touching occurs between view drawings;

FIG. 31 illustrates a correction example in which datum shortening is performed when touching occurs between a view drawing and a drawing frame;

FIG. 32 illustrates a correction example in which datum shortening is performed when touching occurs between a view drawing and a drawing frame;

FIG. 33 illustrates a view drawing before the datum shortening;

FIG. 34 illustrates an algorithm of the datum shortening;

FIG. 35 illustrates a view drawing example after the datum shortening;

FIGS. 36A through 36C illustrate patterns of the datum shortening;

FIGS. 37A through 37C illustrate patterns of the datum shortening;

FIG. 38 illustrates how pieces of the PMI overlap each other with display locations of the PMI changed when the view of the 3D model data is simply converted into the 2D drawing data;

FIG. 39 illustrates the 2D drawing data that is placed when spacing between the pieces of the PMI are enlarged in advance in the 3D model data;

FIG. 40 illustrates PMI display setting parameters in the 3D model data;

FIG. 41 illustrates an example of the PMI display setting parameters;

FIG. 42 illustrates how the 2D drawing generator acquires and stores the PMI display setting parameters from the 3D model data and corrects the display settings of the PMI by applying the PMI display setting parameters stored when the 2D drawing data is generated;

FIG. 43 illustrates how the display color of the PMI in 2D drawing data is changed to red in conjunction with the selection of the corresponding PMI in the 3D model data;

FIG. 44 illustrates how the display color of the PMI in the 3D model data is changed to red in conjunction with the selection of the corresponding PMI in the 2D drawing data; and

FIG. 45 illustrates how the PMI in a PMI tree, the PMI in the 3D model data and the PMI in the 2D drawing data are changed in conjunction in terms of the display form.

### DETAILED DESCRIPTION

Exemplary embodiment of the disclosure is described in detail with reference to the drawings.

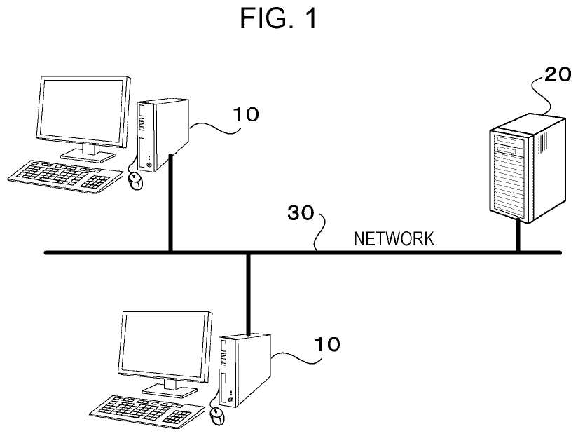

FIG. 1 illustrates a system configuration of a drawing data processing system of an exemplary embodiment of the disclosure.

Referring to FIG. 1, the drawing data processing system includes multiple terminal apparatuses 10 and a drawing data management server 20, mutually connected to each other via a network 30. The drawing data management server 20 manages drawing data including component drawings and product drawing used when a variety of products are designed. The terminal apparatus 10 is an information processing apparatus that have functions of downloading the drawing data managed by the drawing data management server 20, displaying the drawing data, performing a variety of operations on the downloaded drawing data, such as correcting or modifying the downloaded data, and then uploading the processed drawing data to the drawing data management server 20.

The drawing data managed by the drawing data management server 20 is three-dimensional (3D) model data that includes, as product manufacturing information (PMI), not only product shape information indicating the shape of a product, but also specification information about reference dimensions and tolerances. The drawing data management server 20 manages not only the 3D model data but also two-dimensional (2D) drawings produced based on the 3D model data.

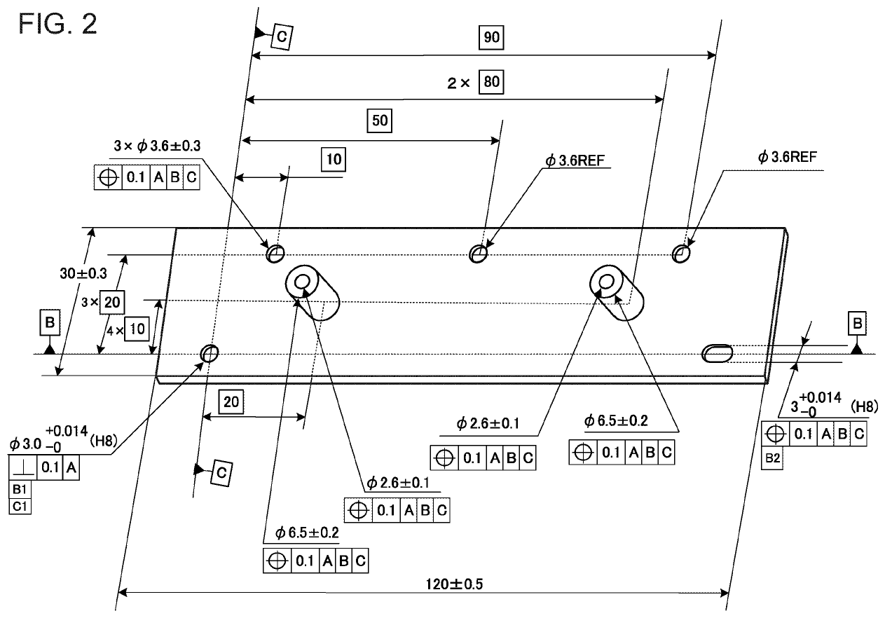

FIG. 2 illustrates an example of the 3D model data including the PMI. Referring to FIG. 2, a variety of PMI, such as size tolerance, geometric tolerance, and theoretically exact dimensions (hereinafter theoretical dimensions), is displayed as a 3D annotation on a 3D model.

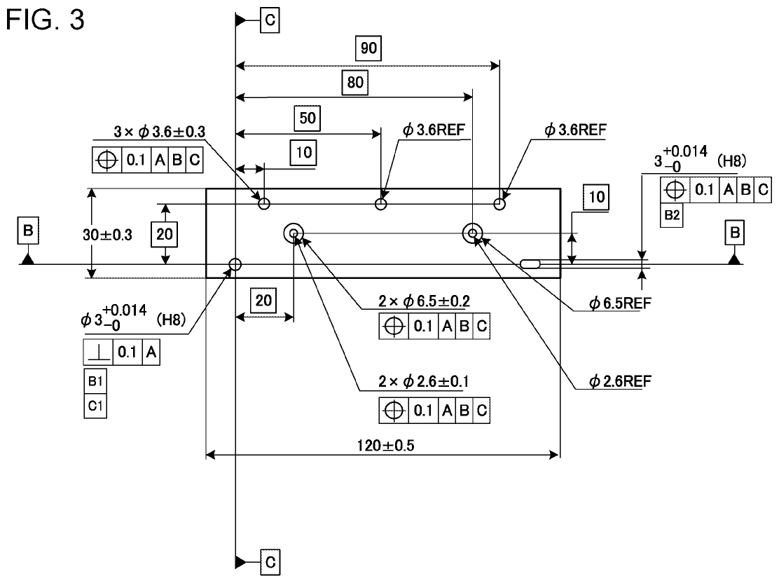

FIG. 3 illustrates an example of the 2D drawing data including the PMI. The 2D drawing data illustrated in FIG. 3 is a 2D drawing into which the 3D model illustrated in FIG. 2 is converted. The variety of PMI, such as size tolerance, geometric tolerance, or theoretical exact dimension, is displayed on the 2D drawing. The 2D drawing data like this may be printed on a paper sheet. In a manufacturing floor where apparatuses, such as personal computers, are not available, a component or a product, designed as a 3D model, may be converted into a 2D drawing and then printed on a paper sheet for use.

When the 2D drawing data is produced from the 3D model representing the shape of a product, multiple 2D projection images (views) resulting from projection of the product in multiple directions are to be produced. The 2D projection images are then to be placed on paper sheets having sheet sizes respectively corresponding to the 2D projection images. When the 2D projection images as 2D drawings are placed, there are a variety of factors of the drawings and a condition that is to be visibly recognized by a user using the drawings. Typically, if the 2D drawing data is produced from the 3D model, the user producing the drawings may produce the 2D drawing data from the 3D model while specifying the layout of each 2D drawing in view of the factors of the drawings and the condition.

In particular, when multiple 2D projection images are difficult to place on a paper sheet region of a single sheet, the user may produce the 2D drawing data in view of which 2D projection image to place on which page and in view of how many paper sheet regions the 2D projection images are to be placed on.

The terminal apparatus 10 in the drawing data processing system of the exemplary embodiment performs a process as described below. When the 2D drawing data including multiple 2D drawings obtained through the projection of a product in multiple directions is produced from the 3D model data representing the product, the 2D drawing data satisfying the factors of the drawings and the condition may be produced without the user performing an operation to specify the layout of the 2D projection image.

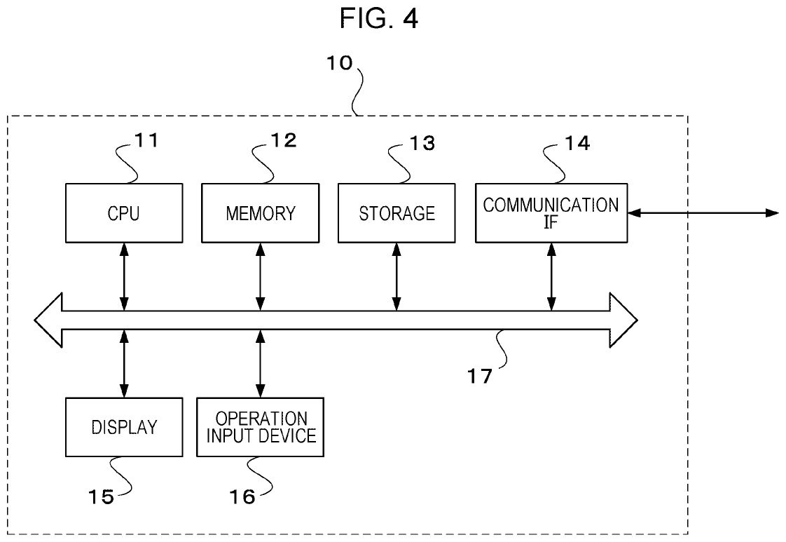

FIG. 4 is a block diagram illustrating a hardware configuration of the terminal apparatus 10 in the drawing data processing system of the exemplary embodiment of the disclosure.

Referring to FIG. 4, the terminal apparatus 10 includes a central processing unit (CPU) 11, memory 12, storage 13, such as a hard disk, communication interface (IF) 14 that transmits data to or receives data from an external apparatus via the network 30, display 15, such as a liquid-crystal display, and operation input device 16 including a touch panel and a keyboard. These elements are interconnected to each other via a control bus 17.

The CPU 11 is a processor that performs a predetermined process in accordance with a control program stored on the memory 12 or the storage 13, thereby controlling the operation of the terminal apparatus 10. According to the exemplary embodiment, the CPU 11 reads the control program from the memory 12 or storage 13 and then executes the read control program. The disclosure is not limited to this method. For example, the control program may be provided in a recorded form on a computer-readable recording medium. For example, the control program may be provided in a recorded form on an optical disk, such as a compact disc read-only memory (CD-ROM) or digital versatile disc ROM (DVD-ROM), or a semiconductor memory, such as a universal serial bus (USB) memory or a memory card. The control program may be acquired from an external apparatus via a communication network connected to the communication IF 14.

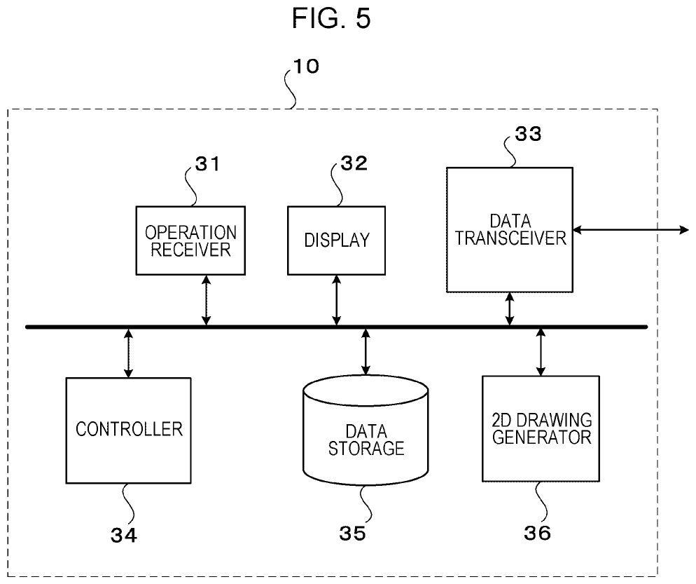

FIG. 5 is a block diagram of a functional configuration of the terminal apparatus 10 that is implemented when the control program is executed.

As illustrated in FIG. 5, the terminal apparatus 10 of the exemplary embodiment includes an operation receiver 31, display 32, data transceiver 33, controller 34, data storage 35, and 2D drawing generator 36.

The data transceiver 33 exchanges data with an external apparatus, such as the drawing data management server 20.

The display 32 is controlled by the controller 34 and displays a variety of information to a user. The operation receiver 31 receives a variety of operations performed by the user.

The controller 34 receives the drawing data from the drawing data management server 20 via the data transceiver 33, causes the data storage 35 to store the drawing data, and causes the display 32 to display the drawing data stored on the data storage 35. In response to a user operation received by the operation receiver 31, the controller 34 modifies the drawing data stored on the data storage 35 and uploads the modified drawing data to the drawing data management server 20 via the data transceiver 33.

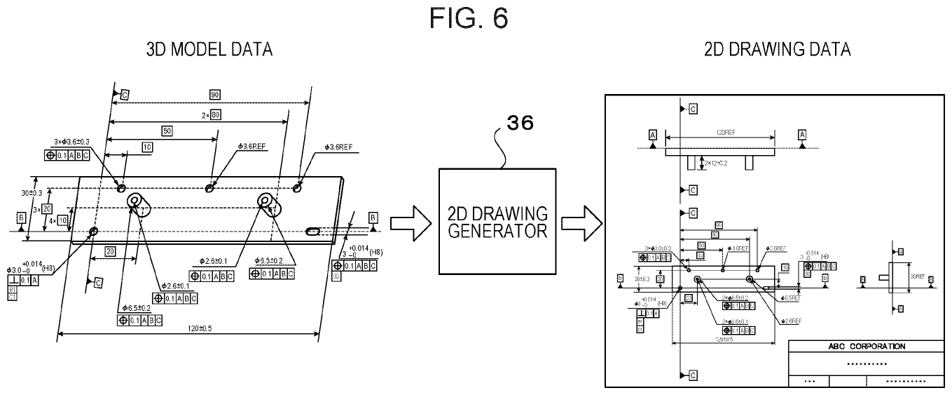

As illustrated in FIG. 6, the 2D drawing generator 36 has a function of converting the 3D model data stored on the data storage 35 into the 2D drawing.

The drawing data is used in a design process and a variety of succeeding processes, including a quotation process, drawing inspection process, mold design process, jig design process, and inspection process. The terminal apparatus 10 thus converts the 3D model data into the 2D drawing data as appropriate and prints the 2D drawing data on paper sheets to be used in a variety of places.

The 2D drawing generator 36 generates multiple 2D projection images as a result of projection of a product in multiple directions from the 3D model data displaying the PMI on the shape of the product. Specifically, the 2D drawing generator 36 generates multiple 2D projection images as a result of projection in two or more directions including a direction indicated by the PMI and directions indicated by a front view, rear view, top view, bottom views, right-side view, and left-side view of the product in the posture of the product at a reference position. The 2D drawing generator 36 may also generate an isometric drawing in which the product is viewed diagonally above.

The 2D drawing generator 36 generates the 2D drawing data that is placed in accordance with a preset layout rule on a paper sheet size (also referred to as a sheet size) and paper regions (also referred to as sheet regions) of a number determined in accordance with the preset layout rule.

Specifically, the 2D drawing generator 36 generates the 2D drawing data by determining a magnification of enlargement/reduction (also referred to as a scaling factor), a sheet size, the number of sections of each sheet, and the number of sheets in a step-by-step manner in accordance with a priority order of at least two layout rules and by placing, in accordance with the layout rule, the generated 2D projection images on the sheet regions of the determined sheet size and the determined number.

The layout rules may include a rule that the 2D projection images including the PMI about a datum target is placed on a firs page. The datum target is a point, a line, or a limited region of a target object that is caused to be in contact with an apparatus or a jig used for processing, measurement, and inspection to set a datum.

The layout rules may include a rule that the 2D projection images corresponding to six basic views in an orthographic projection method are placed on a first page in accordance with a predetermined third angle projection method or a predetermined first angle projection method.

The layout rules may include a rule that each of the 2D projection images is placed on a sheet region having a minimum sheet size that enables each 2D projection image to be accommodated at a set magnification.

The layout rules may include a rule that each of the 2D projection images is placed such that numbers of the 2D projection images to be placed on the sheet regions of pages are equalized with respect to a predetermined range.

The number of pages having the 2D projection images placed thereon may now be three and the total number of 2D projection images may be 11. If five 2D projection images are placed on the first page and five 2D projection images are placed on the subsequent page, only one 2D projection image is placed on the last page. To place equal number of 2D projection images on the sheet region of each page, five 2D projection images are placed on the first page, three 2D projection images are placed on the second page, and then three 2D projection images are placed on the last page.

The layout rules may include a rule that a cross-sectional view representing a cross section of a 2D projection image and/or a detailed view that is an enlarged view of a portion of the 2D projection image are placed on a sheet region of the same page as that of the 2D projection image.

The 2D drawing generator 36 places each of the 2D projection images by applying multiple rules included in the layout rules in accordance with a preset priority order or a priority order specified by a user.

The 2D drawing generator 36 places each of the 2D projection images in a scale enlarged form if a size of the product represented as a 3D model is equal to or below a predetermined threshold.

The 2D drawing generator 36 generates a detailed drawing that results from enlarging a portion of a region that satisfies a preset condition in each of the 2D projection images and places the detailed drawing on a sheet region.

The 2D drawing generator 36 places a 2D projection image on a sheet region wherein the 2D projection image is directly generated or is a detailed drawing that results from enlarging a portion of a region satisfying a preset condition in the 3D model data and is added to the 3D model data.

The 2D drawing generator 36 generates the detailed drawing as the region satisfying the preset condition, wherein the region satisfying the preset condition is a region that includes a portion having a reference dimension equal or below a preset value, a region that includes a portion having a ratio of the portion to a size of a product having the reference dimension, the ratio being equal to or below a preset value, or a region that has a density of a location having a specified reference dimension, the density equal to or higher than a preset value.

The 2D drawing generator 36 places each of the generated 2D projection images on the sheet region such that the generated 2D projection images do not touch each other or do not touch a drawing frame that is printed as an outline frame of the 2D projection images.

The 2D drawing generator 36 divides the sheet region into multiple regions and place respectively the 2D projection images on the regions.

The 2D drawing generator 36 determines whether the 2D projection images touch each other, by converting graphic components included in a 2D projection image described in a vector code format into image data in a raster format and performing touch determination on the image data of the graphic components in the raster format. The 2D drawing generator 36 thus determined whether the 2D projection images touch each other or touch the drawing frame.

The 2D drawing generator 36 notifies a user of an occurrence of touching of the 2D projection images or eliminates the touching by moving one of 2D projection images determined as being in touch with each other or reducing a whole of the 2D projection image in scale or by shortening a portion of the 2D projection image.

If the 2D projection image is generated in accordance with the 3D model data, the 2D drawing generator 36 corrects in advance a display setting of the PMI in the 3D model data such that the display setting of the PMI displayed in the generated 2D projection image is optimized in a 2D drawing.

When the generated 2D drawing data and the 3D model data are displayed on the display 32 and if the PMI on one piece of data of the 3D model data and the 2D drawing data is selected, the 2D drawing generator 36 modifies a display form of the PMI on the other piece of data of the 3D model data and the 2D drawing data. For example, if the PMI on the one piece of data of the 3D model data and the 2D drawing data is selected, the 2D drawing generator 36 modifies not only the display color of the PMI on the one piece of data selected but also the display color of the PMI on the other piece of data in conjunction

If the generated 2D drawing data and the 3D model data are displayed on the display 32 and the PMI on one piece of data of the displayed 3D model data and the displayed 2D drawing data is selected, the 2D drawing generator 36 outputs not only information identifying the PMI on the other piece of data of the 3D model data and the 2D drawing data but also a combination of the 3D model data and the 2D drawing data.

In the following discussion, the paper region having the 2D projection image placed thereon is referred to as a sheet region and the size of the sheet region is referred to as a sheet size. Also in the following discussion, the 2D projection image generated from a view included in the 3D model is simply referred to as a view.

The operation of the terminal apparatus 10 in the drawing data processing system of the exemplary embodiment is described in detail with reference to the drawings.

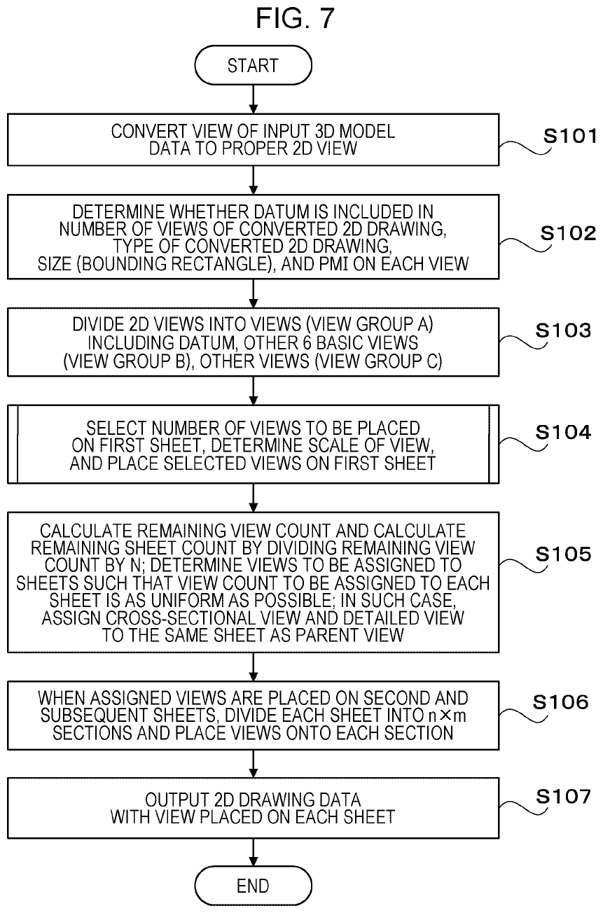

FIG. 7 is a flowchart illustrating the operation of the 2D drawing generator 36 that generates the 2D drawing data from the 3D model data.

In step S101, the 2D drawing generator 36 converts each view included in the input 3D model data into a 2D projection image such that the 2D projection image is appropriate as a 2D drawing. How the 2D drawing generator 36 specifically converts each view included in the input 3D model data into an appropriate 2D drawing is described below.

In step S102, the 2D drawing generator 36 determines whether a datum is included in a view count and type of the converted 2D drawing, size of a bounding rectangle, and PMI on each view.

In step S103, the 2D drawing generator 36 sorts 2D drawings into a view group A including datum, a group B including other six basic views, and a view group C including other views.

In step S104, the 2D drawing generator 36 selects the number of views N to be placed on the first page, determines a scaling factor of each view, and places the 2D drawings of the selected number onto the first sheet.

In step S105, the 2D drawing generator 36 calculates a remaining view count and calculates a remaining sheet count by dividing the calculated view count by N. The 2D drawing generator 36 determines the views to be assigned to sheets such that the view count per each sheet is as uniform as possible. In this case, if possible, the 2D drawing generator 36 assigns a cross-sectional view and a detailed view to the same sheet as a parent view that serves as a source view.

In step S106, the 2D drawing generator 36 places the views assigned to each sheet onto the second and subsequent sheets. In this case, the 2D drawing generator 36 divides each sheet into n×m sections and places respectively the views onto the sections.

In step S107, the 2D drawing generator 36 outputs the 2D drawing data placed to each sheet.

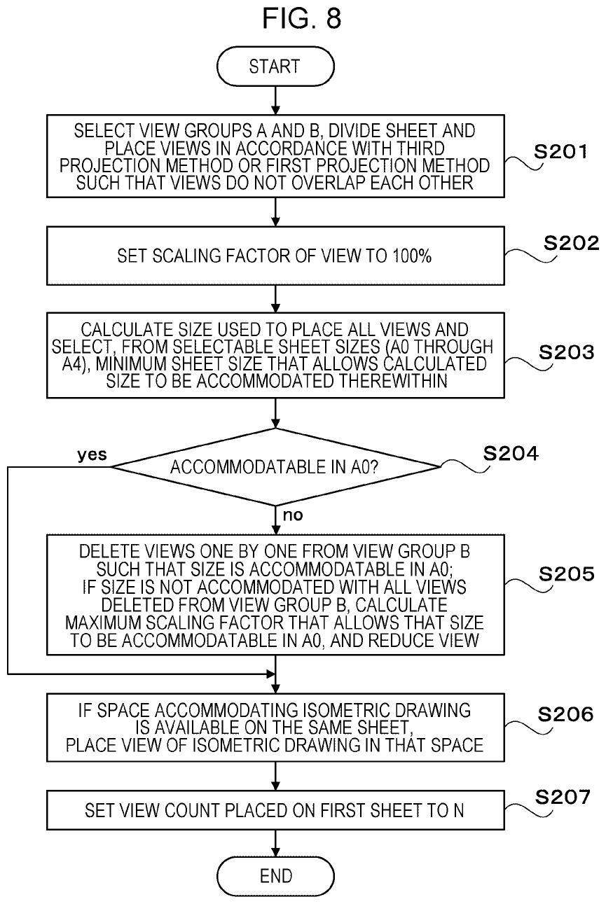

FIG. 8 is a flowchart illustrating a detailed placement operation of a view on the first sheet described with reference to step S104 in the flowchart in FIG. 7.

In step S201, the 2D drawing generator 36 selects the view groups A and B, divides the sheet, and places the views such that the views do not overlap each other in accordance with the third projection method or the first projection method. In this case, the placement is performed such that the vertical position and horizontal position of each datum axis included in each view are aligned between adjacent views.

Each of the third projection method and first projection method is one of drafting methods and represents the shape of a product by placing, on a sheet, six basic drawings including a front view, plan view, right-side view, left-side view, rear view, and bottom view.

In step S202, the 2D drawing generator 36 sets the initial value of a view scaling factor to 100%.

In step S203, the 2D drawing generator 36 calculates the size used to place all selected views and selects from selectable sheet sizes (A0 through A4) a minimum sheet size that allows the size to be accommodated therewithin.

In step S204, the 2D drawing generator 36 determines whether the size used to place all the views is accommodatable within the size A0.

If the 2D drawing generator 36 has determined in step S204 that the size used to place all the views is not accommodatable in the size A0, the 2D drawing generator 36 deletes in step S205 views one by one from the view group B until the size is accommodatable in the size A0. If the size is not accommodatable in the size A0 even with all the views deleted from the view group B, the 2D drawing generator 36 calculates a maximum scaling factor at which all the views in the view group A are accommodatable in the size A0 and reduces the views in the view group A at the calculated scaling factor.

In step S206, if space accommodating an isometric drawing is available on the same sheet, the 2D drawing generator 36 places the view of the isometric drawing in the space.

Finally, in step S207, the 2D drawing generator 36 sets the view count of the views placed on the first sheet to N and then ends the process.

If the 2D drawing generator 36 has determined in step S204 that the size used to place all the views is accommodatable in the size A0 or a smaller size, the 2D drawing generator 36 ends the process after performing steps S206 and S207.

Through this process, all the views including datums in the view group A are placed on the first sheet of the 2D drawing.

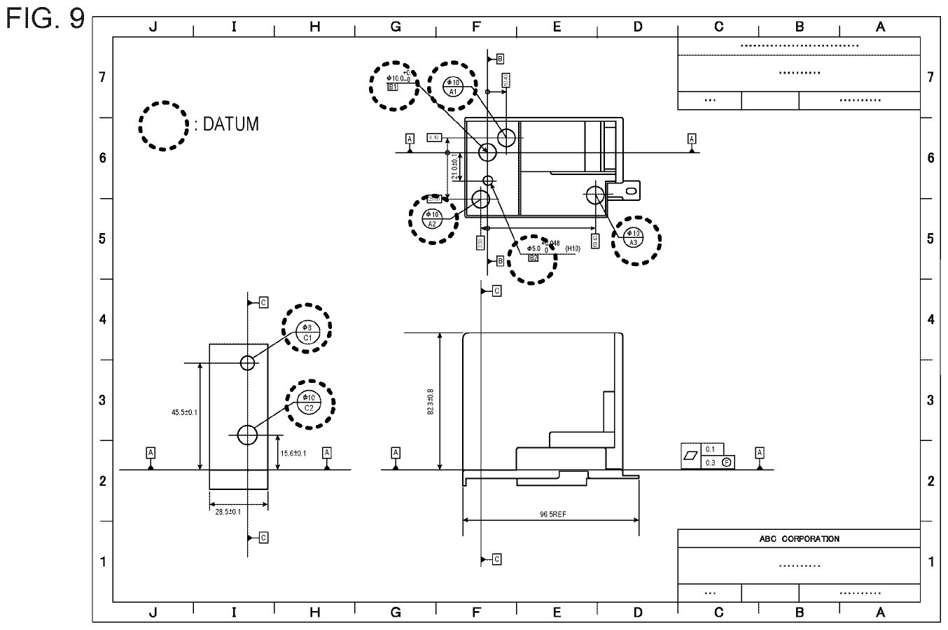

FIG. 9 illustrates an example of the 2D drawings where the views including the datums are placed on the first sheet. Referring to FIG. 9, views including datums represented by the PMI including characters A1 through A3, B1, B2, C1, and C2 are placed on the first sheet of the 2D drawing. The datums refer to a reference plane, a reference line, or a reference point, serving as a geometric criterion that is used to determine geometric tolerance. The PMI including the characters A1 through A3, B1, B2, C1, and C2 is PMI related to the reference plane, reference line, or reference point and indicates a position used to identify the datum.

The flowchart in FIG. 8 illustrates an example of a process in which the 2D drawing generator 36 generates the 2D drawing by prioritizing a layout rule in which a 2D projection image including the PMI related to the reference plane, reference line or reference point is placed on the first page. In the 2D drawing generated through the process illustrated in the flowchart in FIG. 8, all the views including the datums are placed on the first page.

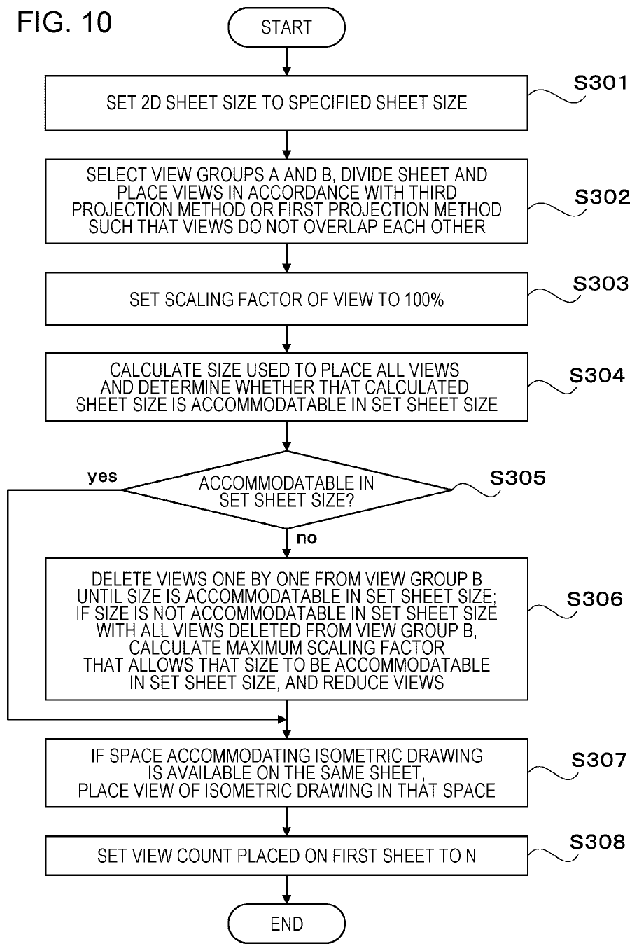

FIG. 10 is a flowchart illustrating an operation of the 2D drawing generator 36 when prioritizing a layout rule to use a specified sheet size is selected. The flowchart in FIG. 10, like the flowchart in FIG. 8, illustrates the details of the placement operation of the views on the first page described in step S104 in the flowchart in FIG. 7.

In step S301, the 2D drawing generator 36 sets the sheet size of the 2D drawing to a specified sheet size. For example, the sheet size may be set to the size A1.

In step S302, the 2D drawing generator 36 selects the view groups A and B, divides the sheet, and places the views in accordance with the third projection method or the first projection method such that the views do not overlap each other.

In step S303, the 2D drawing generator 36 sets the initial value of the scaling factor of the views to 100%.

In step S304, the 2D drawing generator 36 calculates the size used to place all the views selected and determines whether the calculated size is accommodatable the size A1 as the set sheet size.

If the determination results in step S304 indicate that the size used to place all the selected views are not accommodatable in the size A1 as the set sheet size (no path in step S305), the 2D drawing generator 36 deletes the views one by one from the view group B in step S306 until the size is accommodatable in the set sheet size. If the size is not accommodatable in the size A1 as the set sheet size with all the views deleted from the view group B, the 2D drawing generator 36 calculates a maximum scaling factor that all the remaining views in the view group A are accommodatable in the size A1 as the set sheet size and reduces the views in the view group A by the resulting scaling factor.

If space allowing the isometric drawing to be placed therewithin is available on the same sheet in step S307, the 2D drawing generator 36 places the isometric drawing in the space.

Finally, the 2D drawing generator 36 sets the view count placed on the first sheet to N and then ends the process in step S308.

If the size allowing all the views to be placed is determined to be accommodatable in the size A1 as the set sheet size in step S305, the 2D drawing generator 36 performs the operations in steps S307 and S308 and then ends the process.

Through the process described above, the 2D drawing data with the specified sheet size prioritized is thus generated.

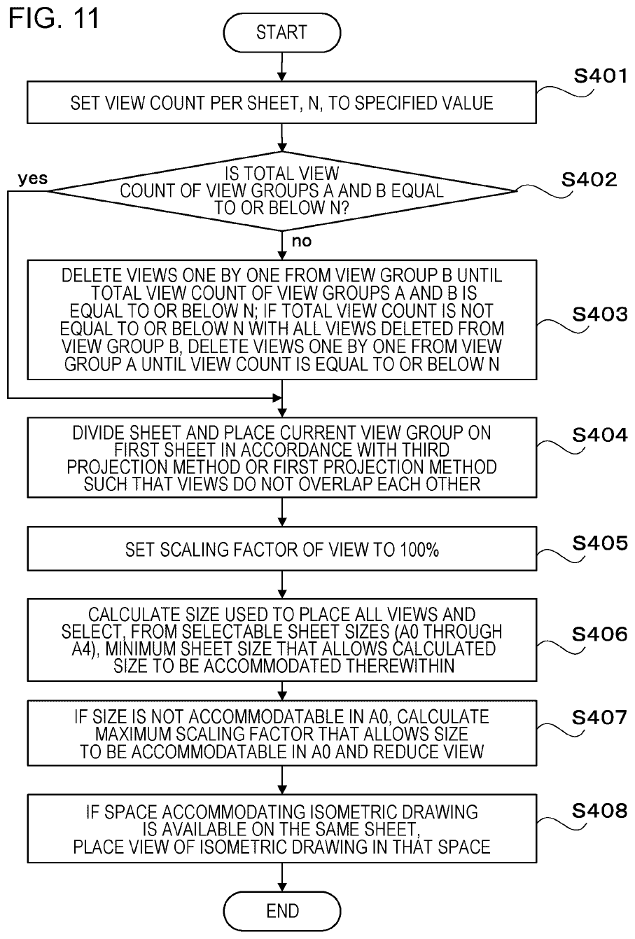

FIG. 11 is a flowchart illustrating an operation of the 2D drawing generator 36 when prioritizing a view count to be placed on the first page is selected. The flowchart in FIG. 11, like the flowcharts in FIGS. 8 and 10, illustrates the details of the placement operation of the views on the first page described in step S104 in the flowchart in FIG. 7.

In step S401, the 2D drawing generator 36 sets the view count N to be placed per sheet to a specified value. For example, the view count N per sheet may be set to six.

In step S402, the 2D drawing generator 36 determines whether the total view count as a sum of the views in the view groups A and B is equal to or below the specified view count N.

If the 2D drawing generator 36 has determined in step S402 that the total view count of the view groups A and B is above the specified view count N, the 2D drawing generator 36 deletes the views one by one from the view group B until the total view count is equal to or below N in step S403. If the total view count is above N with all the views deleted from the view group B, the 2D drawing generator 36 deletes the views one by one from the view group A until the total view count is equal to or below N.

In step S404, the 2D drawing generator 36 divides the sheet and places the views such that the views do not overlap each other in accordance with the third projection method and first projection method.

In step S405, the 2D drawing generator 36 sets the initial value of a view scaling factor to 100%.

In step S406, the 2D drawing generator 36 calculates the size used to place all views included in the present view group and selects from selectable sheet sizes, for example, A0 through A4, a minimum sheet size that allows the size to be accommodated therewithin.

If the size used to place all the views is not accommodatable in the size A0 in step S407, the 2D drawing generator 36 calculates a maximum scaling factor at which all the views in the view group A are accommodatable in the size A0 and reduces the view group A at the calculated scaling factor.

In step S408, if space accommodating an isometric drawing is available on the same sheet, the 2D drawing generator 36 places the view of the isometric drawing in the space and ends the process.

If the 2D drawing generator 36 has determined in step S402 that the total view count of the view groups A and B is equal or below N, the 2D drawing generator 36 performs the operations in steps S404 through S408 and then ends the process.

Through the process described above, the 2D drawing data with the view count per sheet equal to or below the specified value is thus generated.

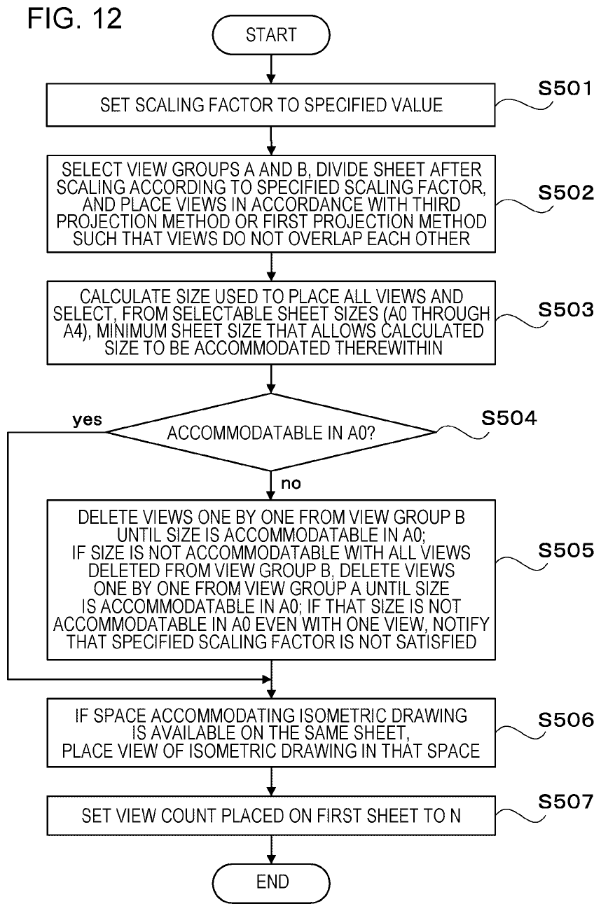

FIG. 12 is a flowchart illustrating an operation of the 2D drawing generator 36 when prioritizing the scaling factor is selected. The flowchart in FIG. 12, like the flowcharts in FIGS. 8, 10, and 11, illustrates the details of the placement operation of the views on the first page described in step S104 in the flowchart in FIG. 7.

In step S501, the 2D drawing generator 36 sets the scaling factor to a specified value. For example, the 2D drawing generator 36 may set the scaling factor to 100%.

In step S502, the 2D drawing generator 36 selects the view groups A and B, scales the view groups A and B by the specified scaling factor, divides the sheet, and places the views such that the views do not overlap each other in accordance with the third projection method or first projection method.

In step S503, the 2D drawing generator 36 calculates the size used to place all views included in the view groups A and B after being scaled and selects from selectable sheet sizes, for example, A0 through A4, a minimum sheet size that allows the size to be accommodated therewithin.

In step S504, the 2D drawing generator 36 determines whether the size used to place all the views is accommodatable within the size A0.

If the 2D drawing generator 36 has determined in step S504 that the size used to place all the views is not accommodatable in the size A0, the 2D drawing generator 36 deletes in step S505 views one by one from the view group B until the size is accommodatable in the size A0. If the size is not accommodatable in the size A0 even with all the views deleted from the view group B, the 2D drawing generator 36 deletes the views one by one from the view group A until all the views are accommodatable in the size A0. If the views even with the number of views in the view group A being one are not accommodatable in the size A0, the 2D drawing generator 36 notifies the user of an error that a scaling factor of 100% is not satisfied since a set scaling factor of 100% is prioritized.

In step S506, if space accommodating an isometric drawing is available on the same sheet, the 2D drawing generator 36 places the view of the isometric drawing in the space.

Finally, in step S507, the 2D drawing generator 36 sets the view count of the views placed on the first sheet to N and then ends the process.

If the 2D drawing generator 36 has determined in step S504 that the size used to place all the views is accommodatable in the size A0 or a smaller size, the 2D drawing generator 36 ends the process after performing steps S506 and S507.

Through this process, the 2D drawing data having the scaling factor as a specified value is thus generated.

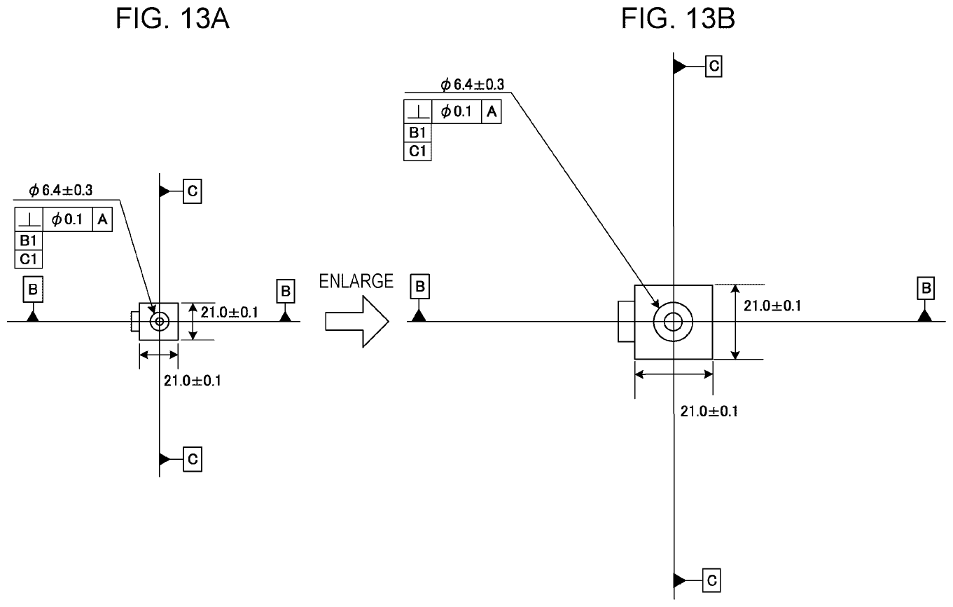

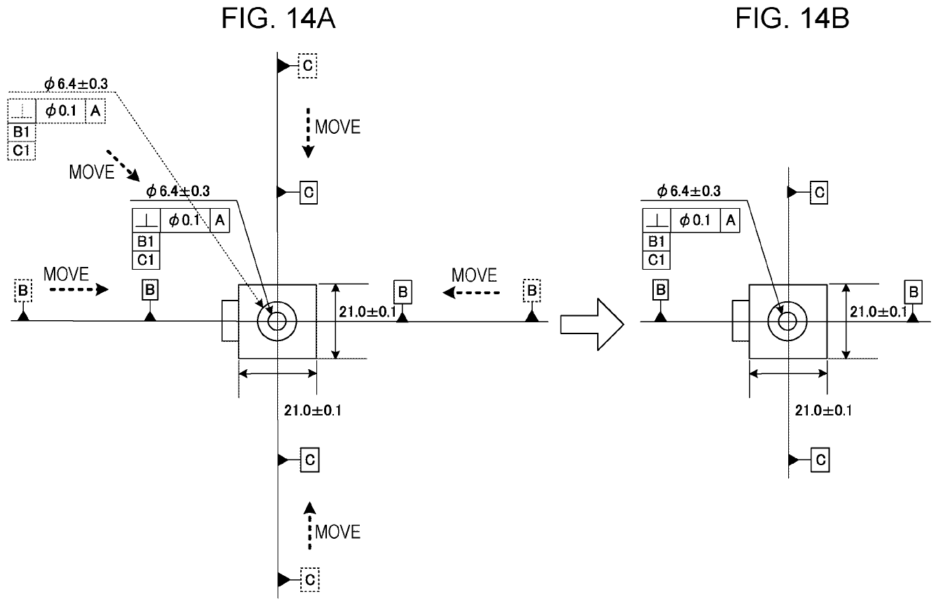

FIGS. 13A through 14B illustrate specific example in which the 2D drawing generator 36 enlarges and places each view of the 2D drawing if the size of a product displayed as the 3D model is equal to or below a preset threshold.

The 2D drawing generator 36 acquires the size of a 2D image portion in the view of the 3D model. If the size is smaller than a specific value, the 2D drawing generator 36 sets the scaling factor such that the size is equal to or above the predetermined size and then performs an expansion operation on the view of the 2D drawing. In the following discussion as illustrated in FIG. 13A, the size of the 2D image portion in the view of the 3D model may now be 21 mm and the predetermined specific value may be 30 mm. The 2D drawing generator 36 enlarges only a component body as the 2D image portion in the view of the 3D model but does not enlarge the characters and drawing size of the PMI portion, and the 2D drawing generator 36 thus performs a conversion operation such that the positional relationship of the 2D image remains unchanged from the original state as much as possible.

If the scaling factor of the view in FIG. 13A is 100%, the 2D drawing generator 36 increases twice the scaling factor of the view, namely increases the scaling factor from 100% to 200% as illustrated in FIG. 13B. Simply increasing the scaling factor increases the entire view, causing the PMI to be positioned at a location corresponding to the magnification. For this reason, as illustrated in FIG. 14A, the PMI is moved to the location with a scaling factor of 100% i such that the PMI is not in touch with the component body.

As a result, the 2D image portion within the view of the 3D model is converted into a 2D drawing in as illustrated in FIG. 14B in which only the component body is enlarged and the whole size of the 2D drawing including the PMI appears almost unchanged from the original size.

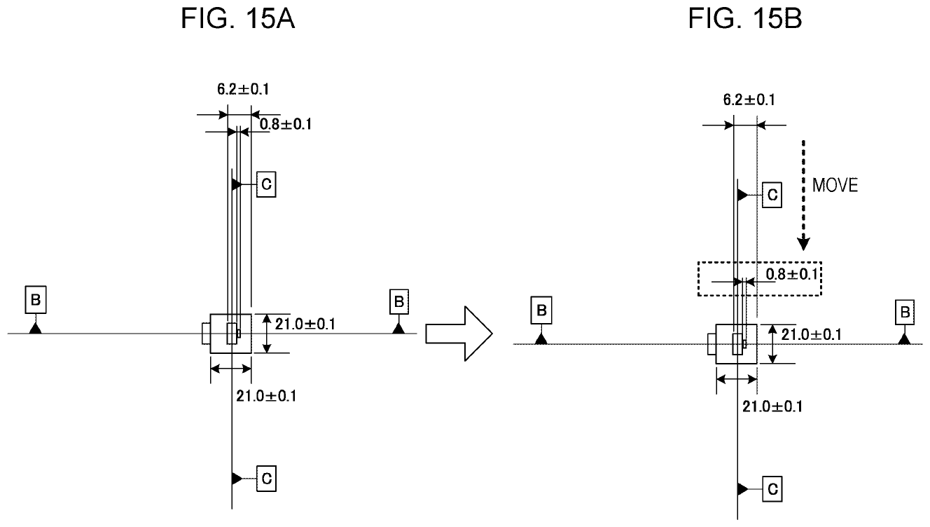

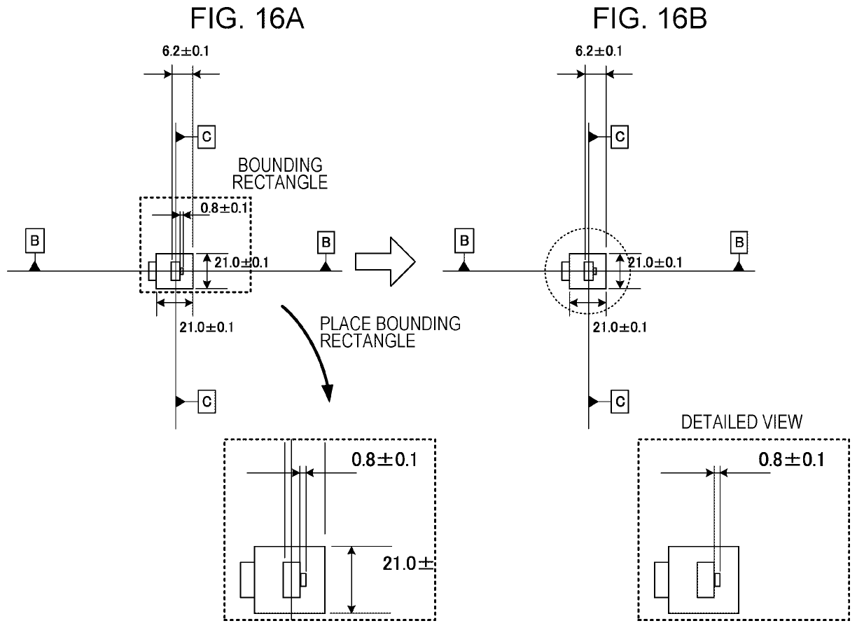

FIGS. 15A through 16B illustrate a specific example in which the 2D drawing generator 36, when generating the view of the 2D drawing, generates a detailed view having a portion enlarged and satisfying a preset condition and places the detailed view on a sheet region.

The 2D drawing generator 36 extracts the PMI having dimensions equal to or below a preset threshold, for example, 2 mm or shorter. The 2D drawing in FIG. 15A has a dimension of 0.8±0.1 mm. The 2D drawing generator 36 thus extracts this PMI from the 3D model in FIG. 15A.

Referring to FIG. 15B, the 2D drawing generator 36 moves the extracted PMI closer to the 2D image of the 3D model.

Referring to FIG. 16A, the 2D drawing generator 36 generates the detailed view by specifying a region of a bounding rectangle surrounding the moved PMI and a 2D image and then places the detailed view in an empty space.

Referring to FIG. 16B, the 2D drawing generator 36 finally hides the PMI in the original view and hides the PMI and the like other than the extracted PMI in the detailed view.

According to the exemplary embodiment, the dimension value and the PMI equal to or below the preset value are extracted. The 2D drawing generator 36 may extract the PMI having a ratio of a dimension value to the size of the whole 3D model being equal to or below a threshold. The threshold may be dynamically determined in response to the scaling factor of the view.

In this way, the 2D drawing generator 36 generates a detailed drawing view including the PMI having the dimension equal to or below the preset threshold in the 3D model.

In accordance with the layout rules described above, the 2D drawing generator 36 places the detailed drawing view as an enlarged portion of a parent view of the 2D drawing together with the parent view on the same sheet region.

When the detailed drawing view is generated, two methods of placing the detailed drawing view may be available. In one method, the generated detailed drawing view is added to the 3D model and then the 3D model is converted into the 2D drawing such that the detailed drawing view is also placed on the 2D drawing. In the other method, the generated detailed drawing view is directly placed on the 2D drawing.

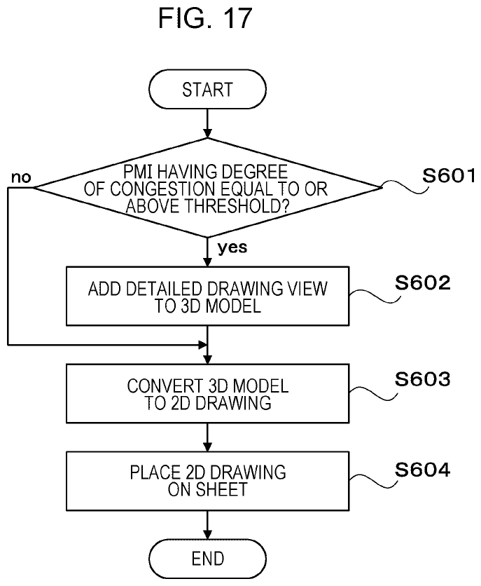

FIG. 17 is a flowchart illustrating the method of placing the detailed drawing view on the 2D drawing (a first addition method of the detailed drawing view) in which the generated detailed drawing view is added to the 3D model and then the 3D model is converted into the 2D drawing.

In the first addition method, the 2D drawing generator 36 determines in step S601 whether PMI having a degree of crowd equal to or above a threshold is present.

If the 2D drawing generator 36 has determined that the PMI having a degree of crowd equal to or above the threshold is present, the 2D drawing generator 36 adds the detailed drawing view to the 3D model in step S602.

The 2D drawing generator 36 converts the 3D model into the 2D drawing in step S603.

and places the 2D drawing onto a sheet in step S604.

If the 2D drawing generator 36 has determined in step S601 that the PMI having the degree of crowd equal to or above the threshold is not present, the 2D drawing generator 36 performs steps S603 and S604 and places the 2D drawing onto the sheet without adding the detailed drawing view.

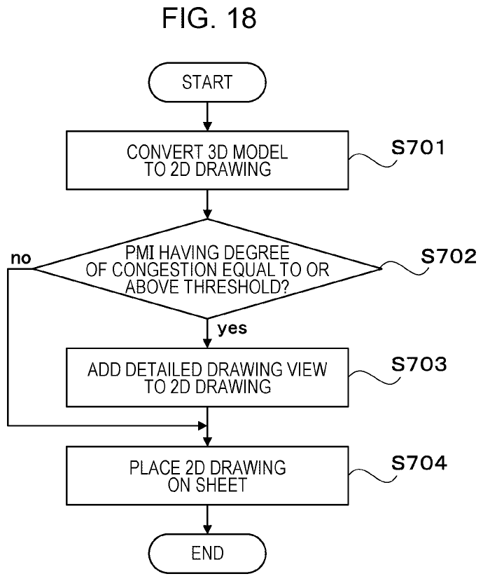

Referring to a flowchart in FIG. 18, the method of directly placing the detailed drawing view onto the 2D drawing (a second addition method of the detailed drawing view) is described below.

In the second addition method, the 2D drawing generator 36 first converts the 3D model into the 2D drawing in step S701.

In step S702, the 2D drawing generator 36 determines in step S702 whether the PMI in the 2D drawing includes the PMI having a degree of crowd equal to or above the threshold.

If it is determined that the PMI in the 2D drawing includes the PMI having a degree of crowd equal to or above the threshold, the 2D drawing generator 36 adds the detailed drawing view to the 2D drawing in step S703.

In step S704, the 2D drawing generator 36 places the 2D drawing with the detailed drawing view added thereto onto the sheet.

If it is determined in step S702 that the PMI in the 2D drawing does not include the PMI having a degree of crowd equal to or above the threshold, the 2D drawing generator 36 places the 2D drawing onto the sheet in step S704 without adding the detailed drawing view.

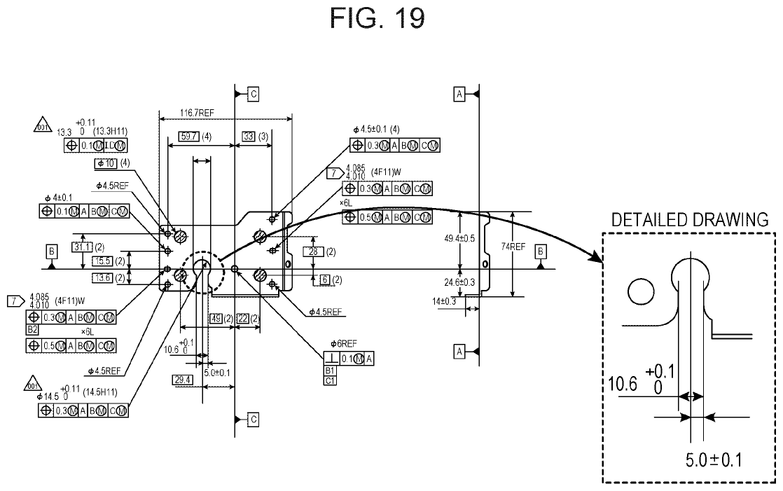

Detection criteria of a location involving using the detailed drawing described in steps S601 in FIGS. 17 and S702 in FIG. 18 is described with reference to FIG. 19.

Referring to FIG. 19, detection methods described below may be used when the PMI having the degree of crowd equal to or above the threshold is detected as a location involving using the detailed drawing.
(1) Detecting location where a relative short reference dimension or a non-relative short reference dimension is present

A non-relative short reference dimension may be detected in the detection method. For example, the PMI of a reference dimension of 2 mm or shorter is detected as a location involving using the detailed drawing. A location of a relative short reference dimension may be detected. For example, the PMI of a reference dimension of 1% or less with respect to a width of a component is detected as a location involving using the detailed drawing.
(2) Detecting location where density of reference dimensions is equal to or above a preset value

If six or more reference points or six or more intersections of dimension lines are present within a specific range of area, for example, 1 cm², that area may be detected as a location involving using the detailed drawing in this detection method.
(3) Detecting location present in a component having longer reference dimension, wider width, or larger size

For example, this detection method detects, as a location involving using the detailed drawing, the PMI present in a component having a reference dimension of 500 mm or longer and a width of 500 mm or longer or in a component having a constant area value or larger.

In the 2D drawing in FIG. 19, a region crowded with dimension lines is detected as a location involving using the detailed drawing.

The 2D drawing generator 36 places multiple generated 2D drawing views respectively on the sheet regions. As described below, this placement operation is performed such that the views of the 2D drawings do not touch each other and such that the views of the 2D drawings do not touch drawing frames printed as outline frames of the 2D drawings.

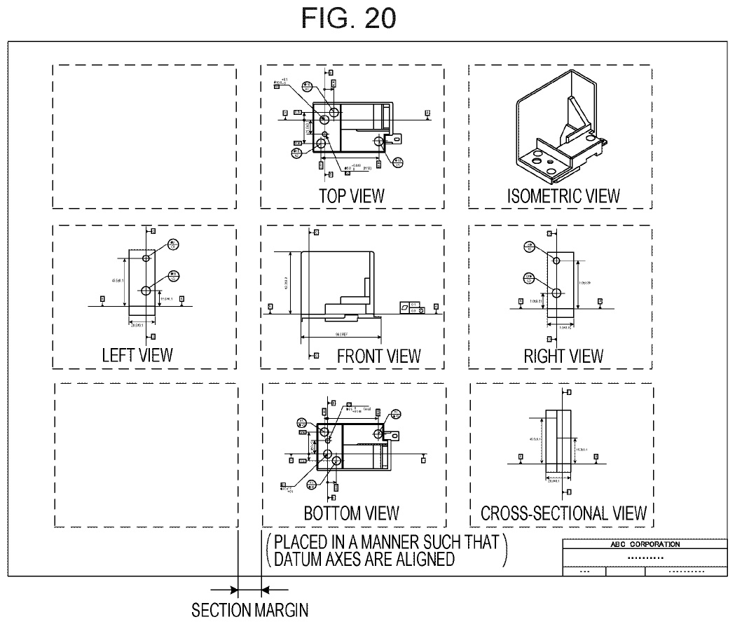

FIG. 20 illustrates how the 2D drawing generator 36 divides the sheet region into multiple regions and places respectively the views onto the divided regions.

The 2D drawing generator 36 sets n×m regions (n and m are positive integers) on the sheet region in response to the number of views to be placed and then places one view on each region. Height and width sizes of each region are determined such that a view including the PMI is accommodated in the region with the horizontal sizes of the views aligned vertically equal each other and the vertical sizes of the views aligned horizontally equal each other. Since pieces of the PMI in the views are different, the sizes used in the view regions for the PMI are different.

When six basic views are placed on a first sheet, the positions of datum axes of the views adjacent to each other in horizontal and vertical directions are aligned in the horizontal and vertical directions. It is noted that if the views are uniformly placed in the centers of the regions, the positions of the datum axes may not be aligned.

Each drawing frame of the sheet has predetermined margins on the top, bottom, left, and right sides thereof, and n×m regions are arranged in the center of the sheet. A predetermined margin is allowed between the regions.

FIG. 20 illustrates that the sheet region is divided into 3×3 regions and a front view, top view, bottom view, left-side view, right-side view, cross-sectional view, and isometric view are respectively placed in the 3×3 regions.

In place of dividing the sheet into the regions and placing respectively the views in the regions, the 2D drawing generator 36 may perform a process as described below that determines whether the views touch each other and whether the views touch the drawing frames and, if any touching occurs, eliminates the touching.

When the sheet region is divided into the regions and the views are respectively placed on the regions as illustrated in FIG. 20, a margin may be too wide even though the views do not touch each other.

The 2D drawing generator 36 then performs the process that places the views onto the sheet region, determines whether the placed views touch each other, determines whether the views touch the drawing frames, and if touching occurs, eliminates the touching.

Through the process, the 2D drawing generator 36 places the views of the 2D drawings onto the sheet region such that the views of the generated 2D drawings do not touch each other and such that the views of the generated 2D drawings do not touch the drawing fames printed as the outline frames of the 2D drawings.

The views of the 2D drawings are typically described in a vector code format, such as scalable vector graphics (SVG). For this reason, the 2D drawing generator 36 converts graphic elements included in the 2D drawing view described in the vector code format into image data in a raster format and then performs touch determination as to whether one piece of the image data of the graphic elements in the raster format touches another piece of the image data. The 2D drawing generator 36 thus determines whether the 2D drawing views touch each other and whether the 2D drawing views touch the drawing frames.

The 2D drawing generator 36 eliminates the touching between the 2D drawing views and the touching between the 2D drawing views and the drawing frames by moving one of two the 2D drawing views determined to be in touch with another or by reducing the 2D drawing views or by shortening part of the 2D drawing views.

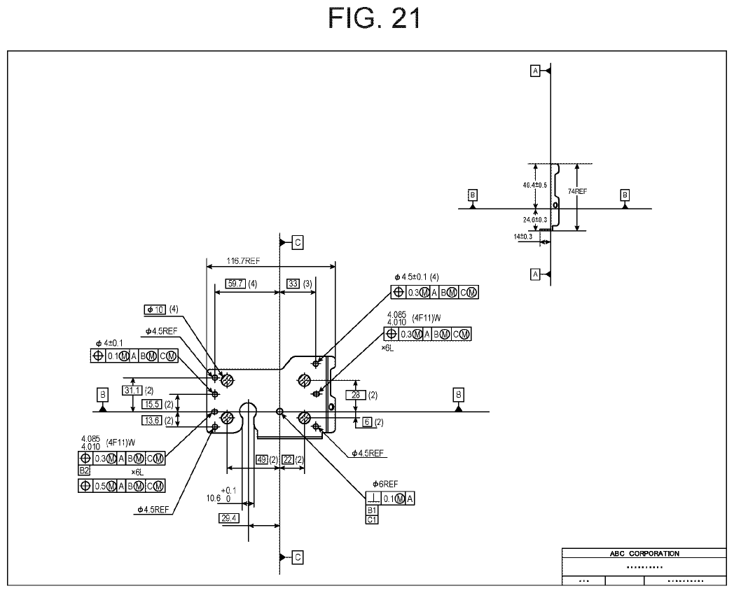

The process of determining the touching between the views is described with reference to FIGS. 21 through 24.

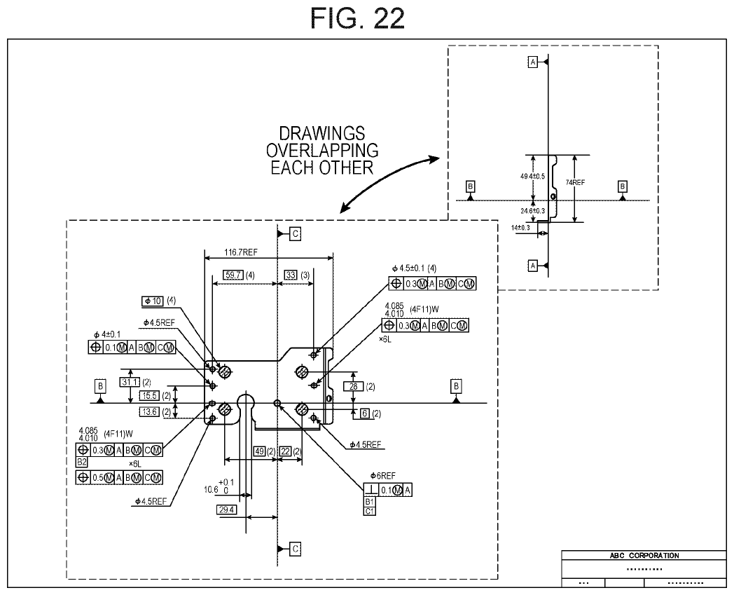

Referring to FIG. 21, the 2D drawing generator 36 places two 2D drawing views on one sheet. As illustrated in FIG. 22, the bounding rectangles of the two 2D drawing views overlap each other and if the regions are set and the 2D drawing views are placed on the regions, the regions also overlap each other. However, if the two 2D drawing views are placed as illustrated in FIG. 21, the two 2D drawing views do not overlap each other.

The 2D drawing generator 36 performs the method described below to determine whether the placed 2D drawing views touch each other and if the 2D drawing views touch each other, the 2D drawing generator 36 perform correction.

Specifically, the 2D drawing generator 36 converts the graphic elements included in each view to a raster image, writes the raster image onto a frame memory, determines label values through a labeling process, and determines the presence or absence of the touching between the views by comparing the label values between different views. If the label values are equal between the different views, the 2D drawing generator 36 determines that the touching has occurred and if the label values are not equal, the 2D drawing generator 36 determines that the touching has not occurred.

The labeling process sets the graphic elements in touch with each other to the same label value and specifically changes a display color in response to the label value.

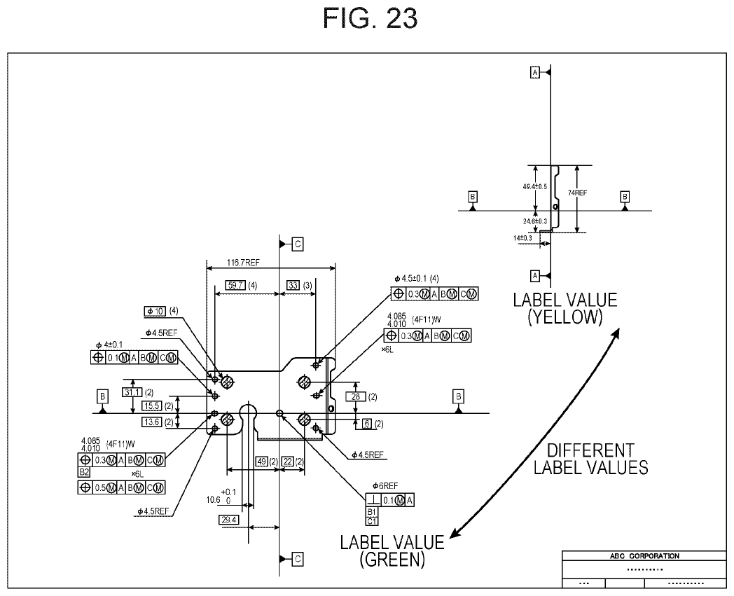

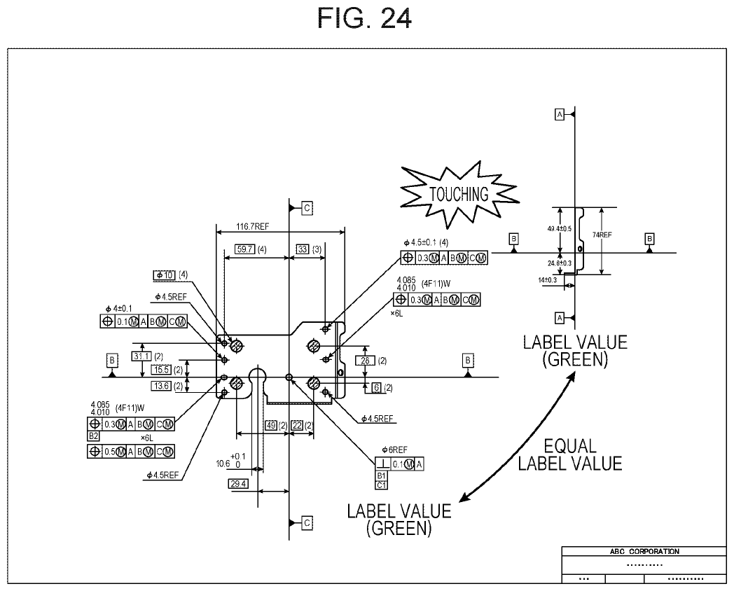

FIGS. 23 and 24 illustrates process examples in which the labeling process has been performed. FIG. 23 illustrates the process example in which no touching has occurred between the view drawings and FIG. 24 illustrates the process example in which touching has occurred between the view drawings.

Since no touching has occurred between the two views in FIG. 23, different label values are set, leading to different display colors. The 2D drawing generator 36 thus determines that no touching has occurred between the two view drawings.

Since touching has occurred between the two views in FIG. 24, the same label value is set, leading to the same display color. The 2D drawing generator 36 thus determines that touching has occurred between the two view drawings.

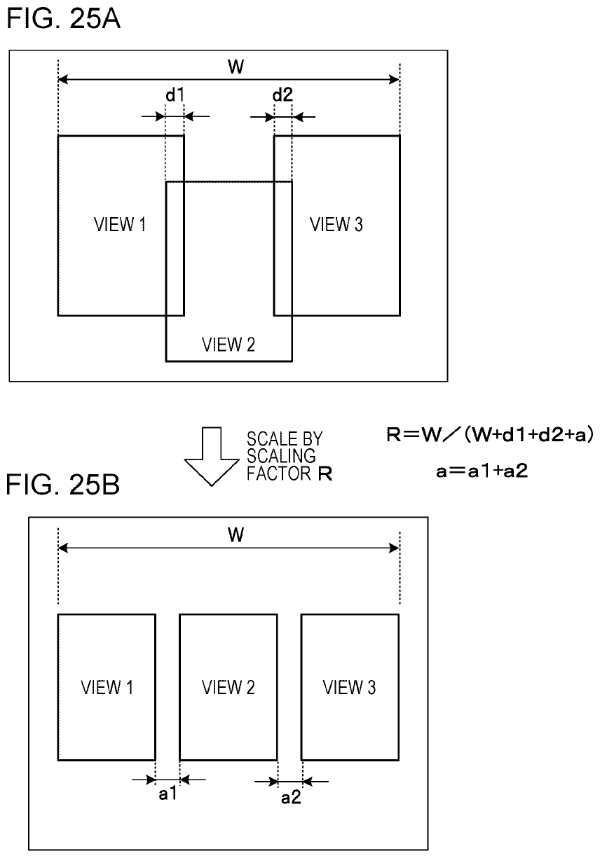

As described below, FIGS. 25A and 25B illustrate a correction method that eliminates the touching between the view drawings by performing a layout correction if the touching is determined to be present between multiple view drawings thus placed.

The 2D drawing generator 36 detects the bounding rectangle of each view drawing that is determined to overlap as illustrated in FIG. 25A and performs the layout correction in accordance with an algorithm described below.

FIG. 25A illustrate three view drawings, views 1 through 3. The width of a portion where the views 1 and 2 overlap is d1 and the width of a portion where the views 2 and 3 overlap is d2. The width that accommodates the views is W and the sum of view gaps between the views after the layout correction is a. The number of views is three. If the view gap between the views 1 and 2 is a1 and the view gap between the views 2 and 3 is a2, a=a1+a2.

Let R represent the scaling factor that is used to perform the layout correction under the above condition, and R is thus calculated in accordance with the following equation:

$$R = W / ( W + d 1 + d 2 + a ) .$$

The 2D drawing generator 36 reduces the view drawings in accordance with the thus calculated scaling factor R and then places the view drawings. Referring to FIG. 25B, the views 1 through 3 may thus be placed on the desired drawing frames.

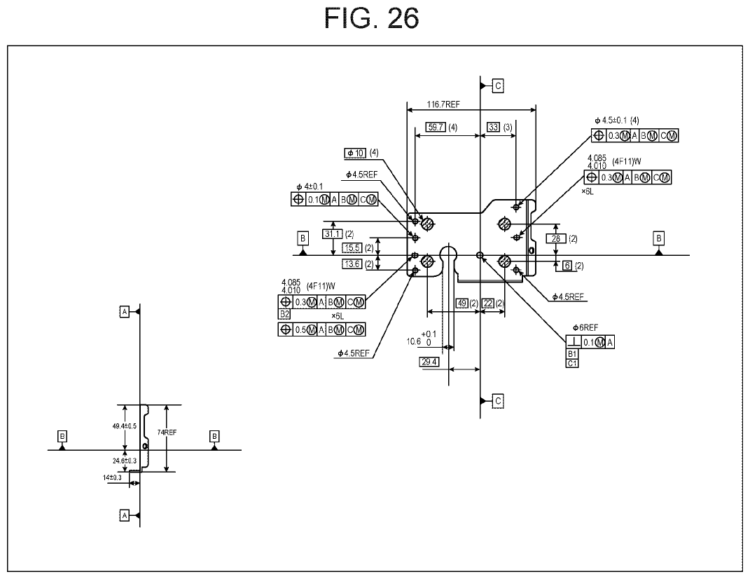

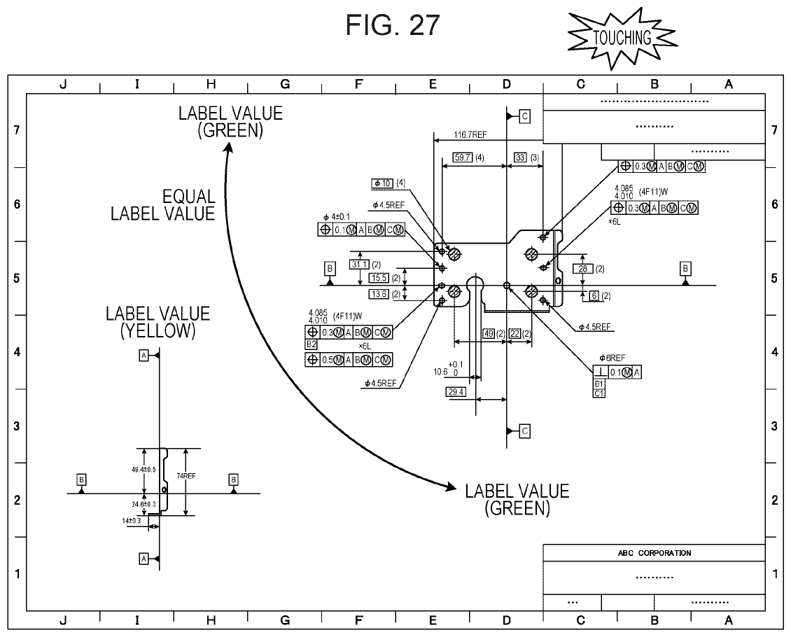

The process to determine the touching between the 2D drawing view and the drawing frame is described below with reference to FIGS. 26 and 27.

As illustrated in FIG. 26, the 2D drawing generator 36 places two 2D drawing views on one sheet. As illustrated in FIG. 27, the 2D drawing generator 36 places the drawing frames on the sheet and then determines whether the 2D drawing views touch the drawing frames.

In this case as well, the 2D drawing generator 36 converts the graphic elements and the drawing frame included in the 2D drawing views described in the vector code format into the image data in the raster format and then performs through the labeling process the touch determination on the image data of the graphic elements in the raster format. The 2D drawing generator 36 thus determines whether the 2D drawing views touches the drawing frames.

Specifically, the 2D drawing generator 36 compares the number of label values with the drawing frame placed on the sheet with the number of label values with the drawing frame not placed on the sheet and if there is no change between the numbers of label values, the 2D drawing generator 36 determines that the touching has occurred. Also, if the 2D drawing view having the same label value as the label value of the placed drawing frame is present, the 2D drawing generator 36 determines that the touching has occurred.

In the touch determination example illustrated in FIG. 27, the drawing frame and the 2D drawing view have the same label value, leading to the same display color. The 2D drawing generator 36 thus determines that the drawing frame touches the 2D drawing view.

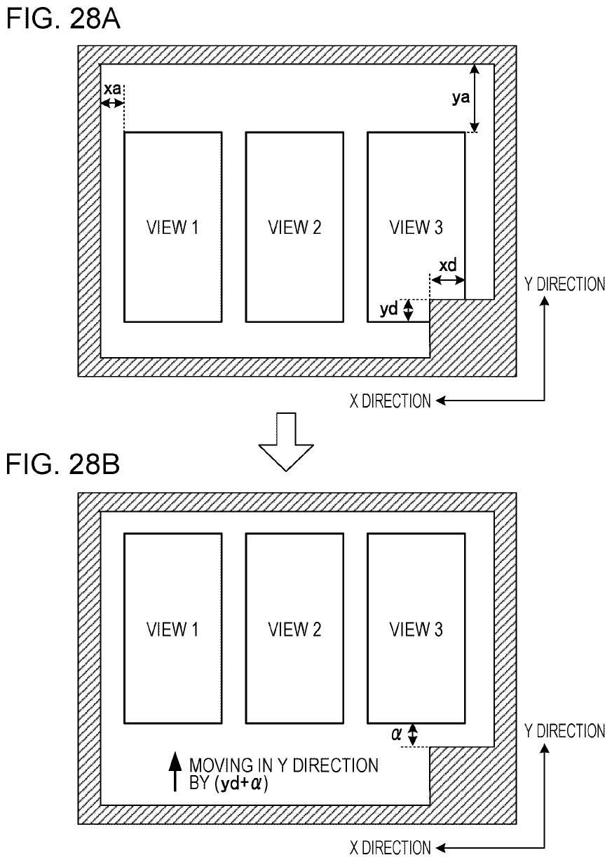

As described with reference to FIGS. 28A and 28B, a correction method eliminates the touching by performing the layout correction when the touching is determined to be present between the 2D drawing view and the drawing frame.

The 2D drawing generator 36 detects the bounding rectangle of each view drawing as illustrated in FIG. 28A. A view 3 partly overlaps the drawing frame by a length xd in an X direction and partly overlaps the drawing frame by a length yd in a Y direction. A margin between the three views 1 through 3 and the drawing frame in the X direction is xa and a margin between the three views 1 through 3 and the drawing frame in the Y direction is ya.

If the widths of the margins xa and ya are respectively longer than the distances xd and yd, the touching may be eliminated by moving the three views 1 through 3 in parallel shift in directions of margin.

Since the margin in the Y direction is larger than the margin in the X direction in FIG. 28A, the touching with the drawing frame may be eliminated by moving the three views in parallel shift by (yd+α) in the Y direction as illustrated in FIG. 28B.

If the widths of the margins xa and ya are respectively shorter than the overlapping distances xd and yd, the touching may be eliminated by reducing the view drawings as illustrated in FIGS. 25A and 25B.

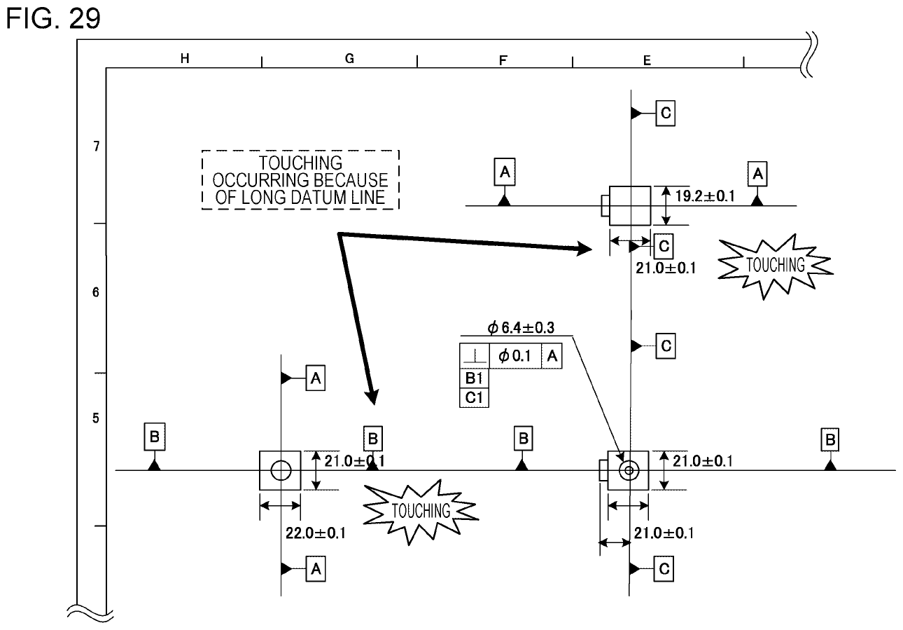

If the touching occurs between the view drawings or between the view drawing and the drawing frame, the touching may be eliminated by shortening the datum lines. FIGS. 29 through 31 illustrate how the touching is eliminated by the datum line shortening.

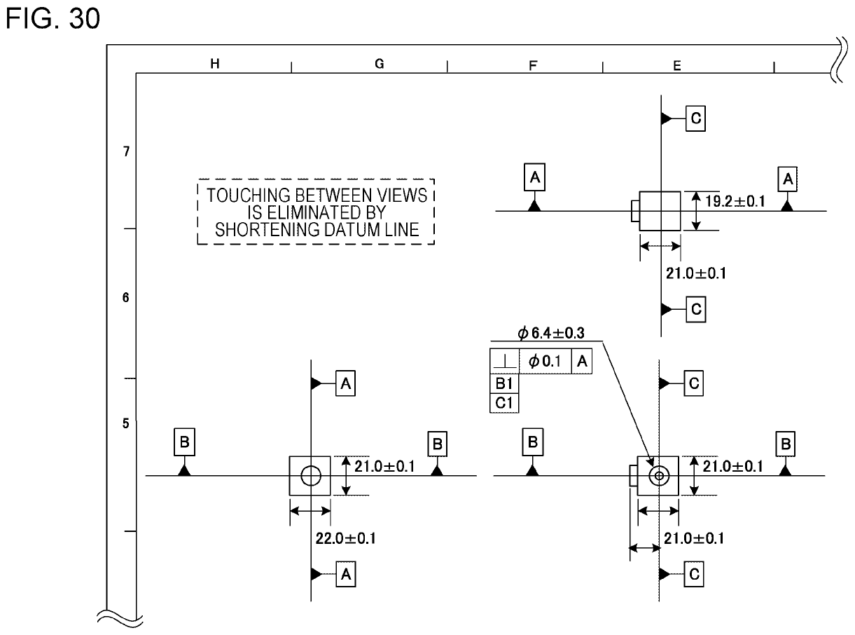

FIG. 29 illustrates the case in which datum axes of three 2D drawing views placed on the same sheet are too long and touch each other. In such a case, shortening the datum axes may eliminate the touching between the 2D drawing views as illustrated in FIG. 30.

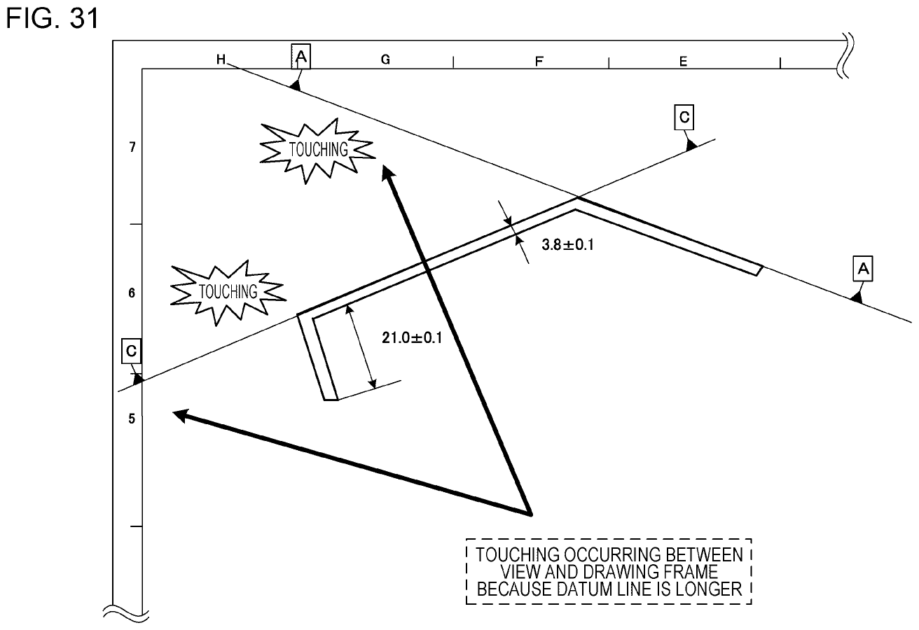

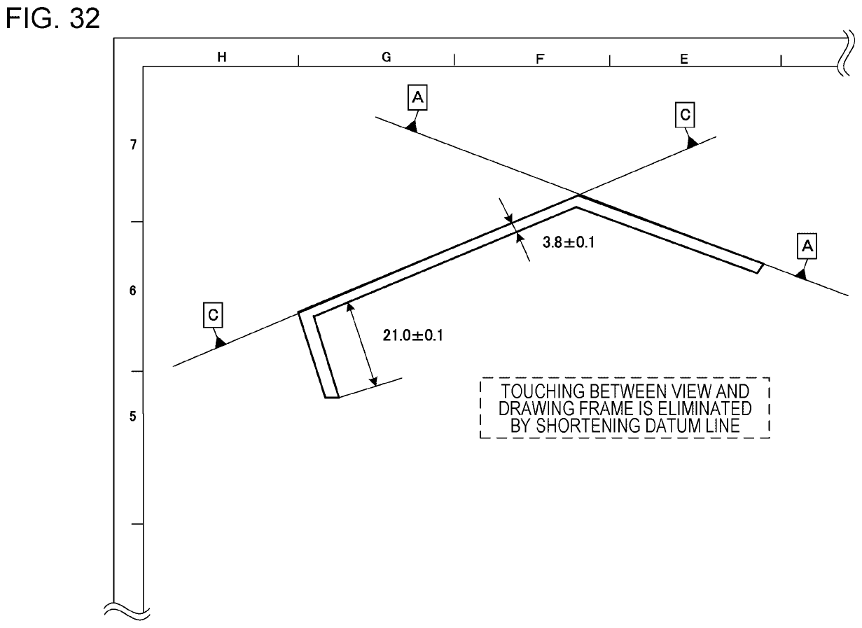

FIG. 31 illustrates the case in which the 2D drawing view and the drawing frame placed on the sheet touch each other because the datum axes of the 2D drawing view are too long. Shortening the datum axes may thus eliminate the touching between the 2D drawing view and the drawing frame as illustrated in FIG. 32.

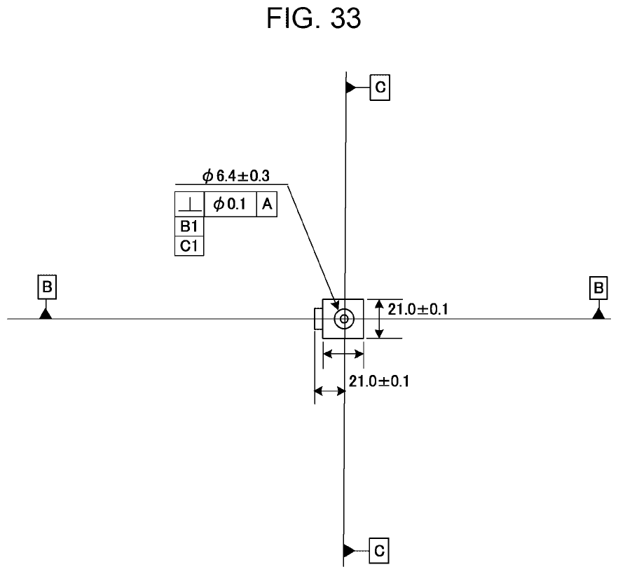

The algorithm to shorten the datum is described with reference to FIGS. 33 through 37.

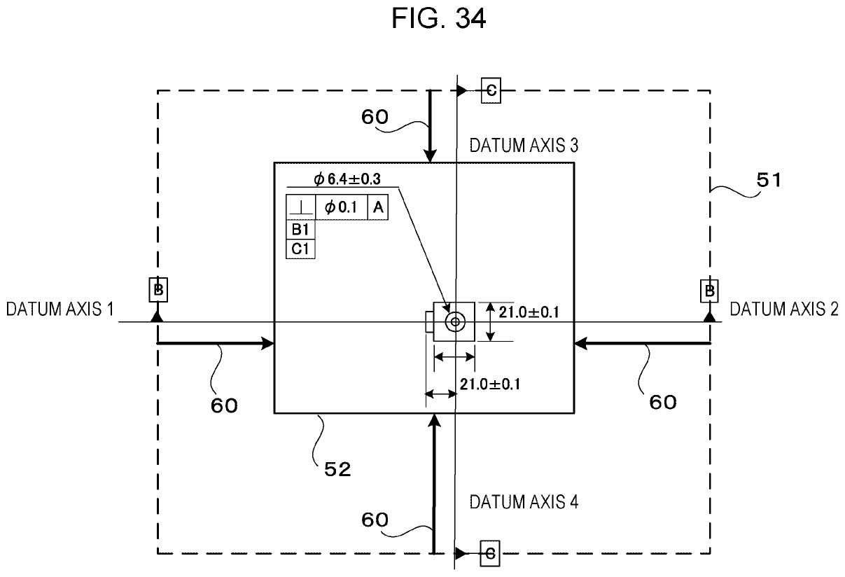

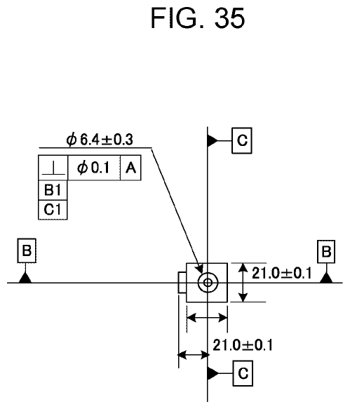

FIG. 33 illustrates a view drawing example before the datum shortening. By analyzing the view drawing in FIG. 33, the 2D drawing generator 36 determines that the view drawing includes datum axes 1 through 4. Referring to FIG. 34, the 2D drawing generator 36 calculates coordinates of a datum outline frame 51 and a drawing body frame 52 of the view drawing. As a result, the 2D drawing generator 36 calculates a shortening vector 60 of each datum axis as illustrated in FIG. 34. The 2D drawing generator 36 thus performs the datum shortening in response to the shortening vector 60 and then outputs SVG data with the datum shortened. FIG. 35 illustrates the output view drawing example after the datum shortening.

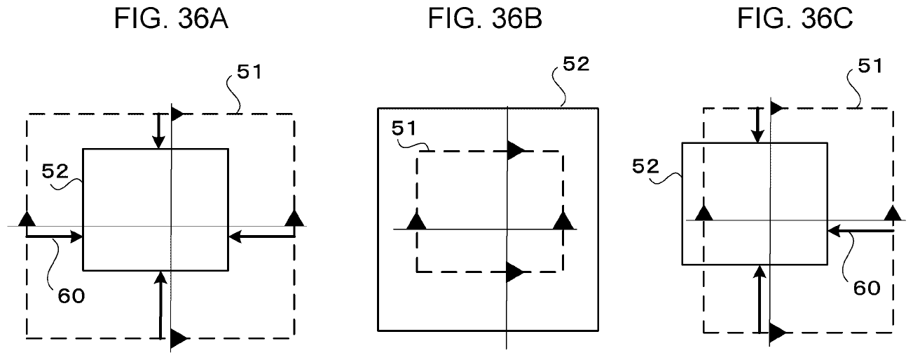

The view drawing in FIG. 33 illustrates four-direction data elements having data axes in four directions and indicates that the datum outline frame 51 is wider than the drawing body frame 52. However, there is a variety of patterns in the datum shortening. For example, FIGS. 36A through 36C illustrate the datum shortening patterns about four-direction datum elements. FIG. 36A illustrates the four-direction datum elements with the datum outline frame 51 wider than the drawing body frame 52. FIG. 36B illustrates the four-direction datum elements with the datum outline frame 51 contained in the drawing body frame 52. The datum shortening is difficult to perform in the case of FIG. 36B. FIG. 36C illustrates the four-direction datum elements with part of the datum outline frame 51 contained in the drawing body frame 52. The datum shortening may be performed in three directions in the case of FIG. 36C.

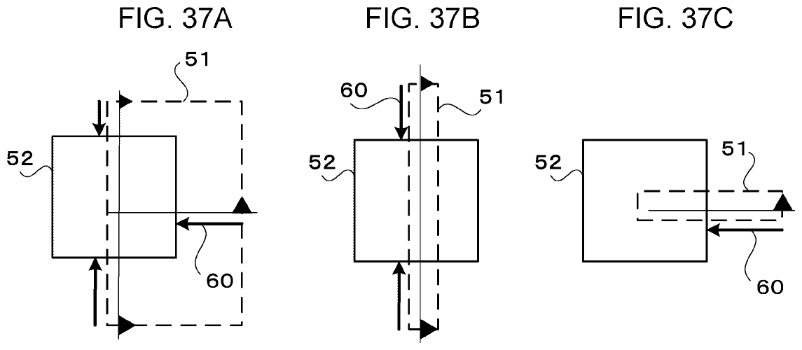

FIGS. 37A through 37C illustrate other patterns of the datum shortening. FIG. 37A illustrates three-direction datum elements and FIG. 37B illustrates two-direction datum elements. FIG. 37C illustrates one-direction datum element.

A variety of datum shortening patterns are present depending the number of datum axes and the size relationship between the datum outline frame 51 and the drawing body frame 52 in the view drawing.

As described below, the 2D drawing generator 36 performs a process that optimizes in the 2D drawing the display setting of the PMI displayed on the 2D drawing view that is generated in accordance with the 3D model data.

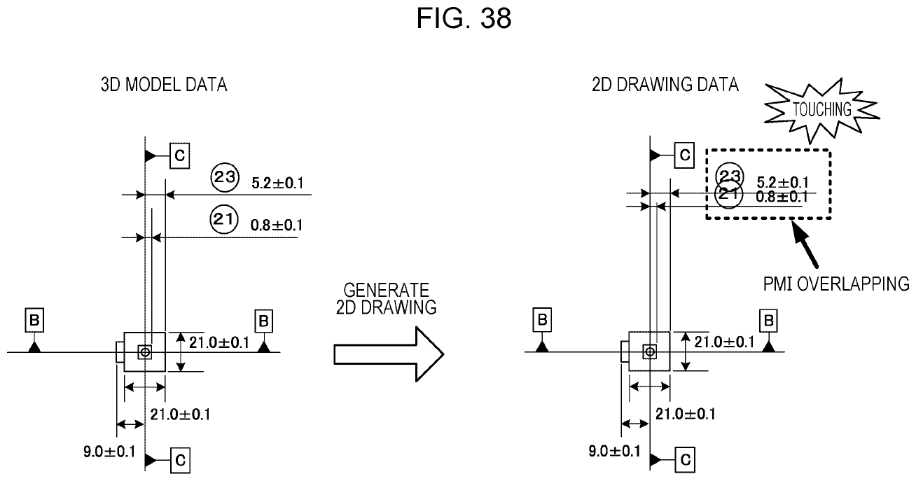

If the view of the 3D model data is simply converted into the 2D drawing data, the display position of the PMI changes as illustrated in FIG. 38 such that the PMI overlaps.

Since the views are individually viewed in in the state of the 3D model data, the layout of the PMI may not cause any problem. When multiple 2D projection images are placed on a single paper sheet, the placement of the PMI may still be subject to some restrictions. For example, pieces of the PMI may be placed above and below a product and an extension of view range may be vertically longer. The views may touch the drawing frame and the number of views may be reduced. In such a case, placing the views to the right and left of the product, the touching with the drawing frame may be controlled. Placing the PMI of the neighboring views in an alternating fashion may increase the number of views that may be accommodated in a single page.

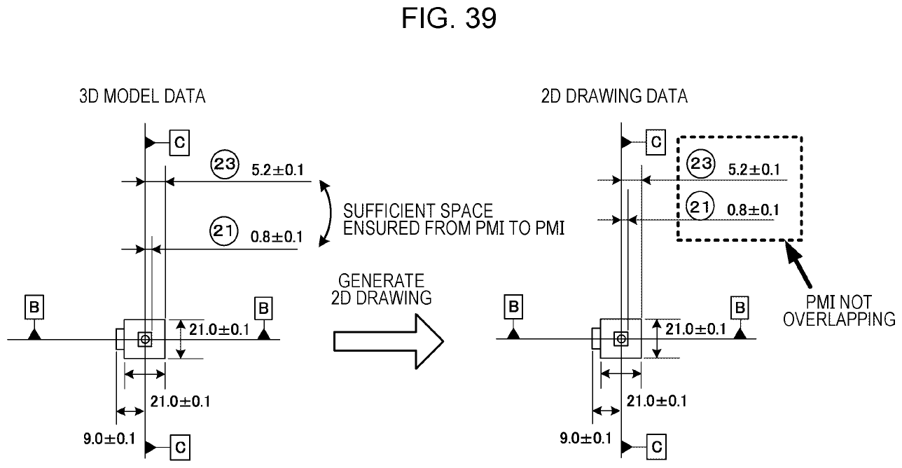

Although the PMI does not overlap in the state of the 3D model data, spacing between pieces of the PMI may be narrowed when the 3D model data is converted into the 2D drawing data. In such a case as illustrated in FIG. 39, the PMI may be placed with the spacing between the pieces of the PMI increased in advance in the 3D model data. In this way, overlapping of the PMI may be controlled when the 3D model data is converted into the 2D drawing data. Conversely, if the spacing between the pieces of the PMI is increased when the 3D model data is converted into the 2D drawing data, the PMI may be placed with the spacing between the pieces of the PMI narrowed in advance in the 3D model data. This correction may be performed by optimizing parameters in accordance with a magnification of enlargement/reduction that is used when the 3D model data is converted into the 2D drawing data. Alternatively, the displaying of the PMI when the 3D model data is converted into the 2D drawing data may be optimized by performing correction on the 3D model data, for example, by adjusting in advance the length of a leader line of a radial dimension in the 3D model data.

The 2D drawing generator 36 may store PMI display setting parameters on the PMI in the 3D model and may then correct the PMI display setting parameters at which the PMI is displayed in each view in the generated 2D drawing. In this way, when the 2D drawing data is generated from the 3D model data, the breaking of the display setting of the PMI in each view drawing included in the 2D drawing data may be controlled.

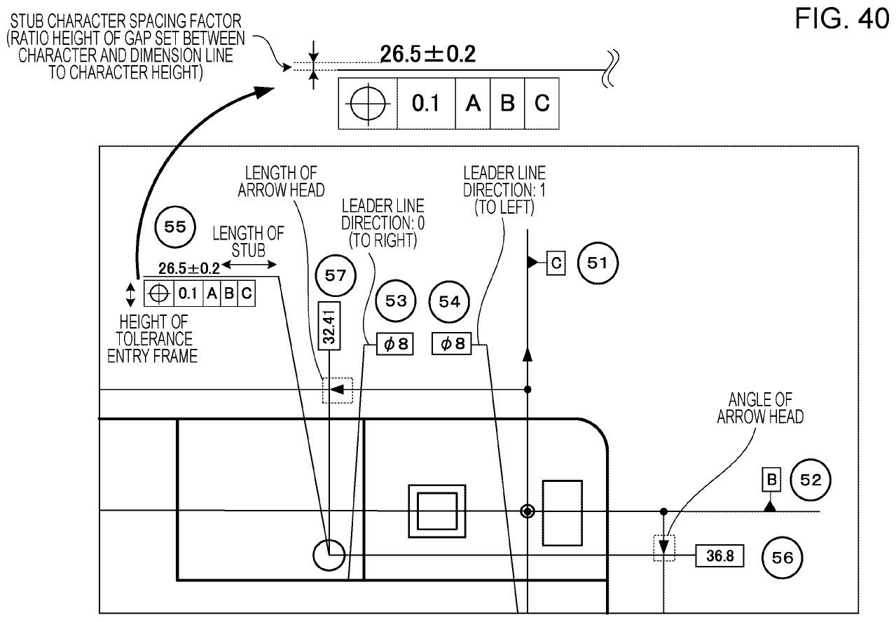

The PMI display setting parameters in the 3D model data is described with reference to FIG. 40. FIG. 40 is an example of a front view in the 3D model data.

The PMI display setting parameters include a height of tolerance entry box, length of an arrow head, direction of an head portion of an inward looking arrow or an outward looking arrow, direction of a leader line, stub length, and stub character spacing factor. The stub character spacing factor is a ratio of a height of spacing set between a character and a dimension line to a height of the character. Specifically, the height of spacing set between the character and the dimension line is calculated by multiplying the height of the character by the stub character spacing factor.

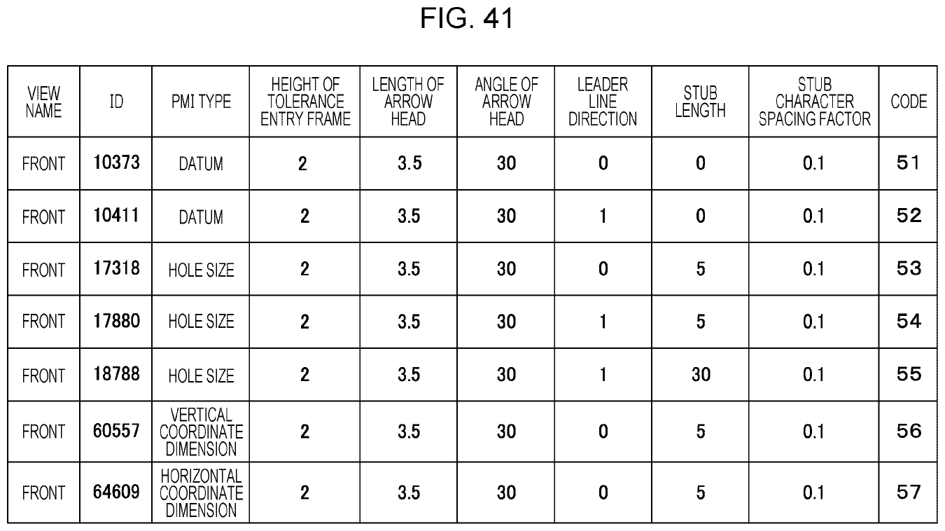

The 2D drawing generator 36 reads the 3D model data, acquires ID (identification information) on each piece of PMI, type information on the PMI, and parameters used to draw the PMI, and stores these pieces of information in a data format, such as comma separated values (CSV). FIG. 41 illustrates thus stored PMI display setting parameters. Information illustrated in FIG. 41 stored for each piece of PMI included in the front view illustrated in FIG. 40 includes a view name, identification information (ID), PMI type, height of tolerance entry frame, length of arrow head, angle of arrow head, leader line direction, stub length, stub character spacing factor, and the like.

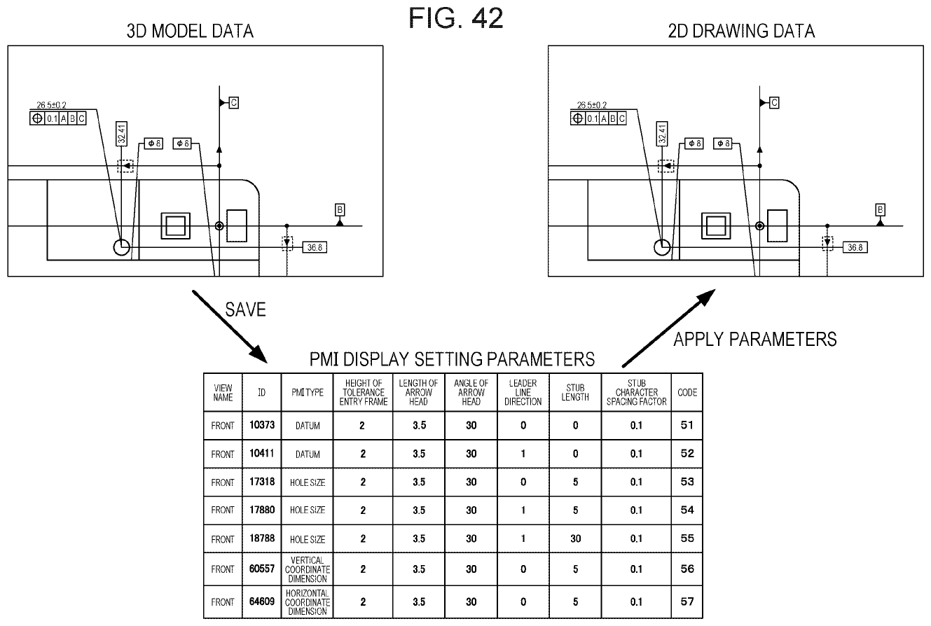

As illustrated in FIG. 42, the 2D drawing generator 36 acquires the PMI display setting parameters from the 3D model data and stores the PMI display setting parameters. When the 2D drawing data is generated, the 2D drawing generator 36 corrects the PMI display setting using the PMI display setting parameters.

This may control the occurrence in which when the 2D drawing data is generated from the 3D model data, the PMI display setting is broken in response to different leader line direction and different arrow head direction and the PMI in the 3D drawing and the PMI in the 2D drawing are mistaken as being different.

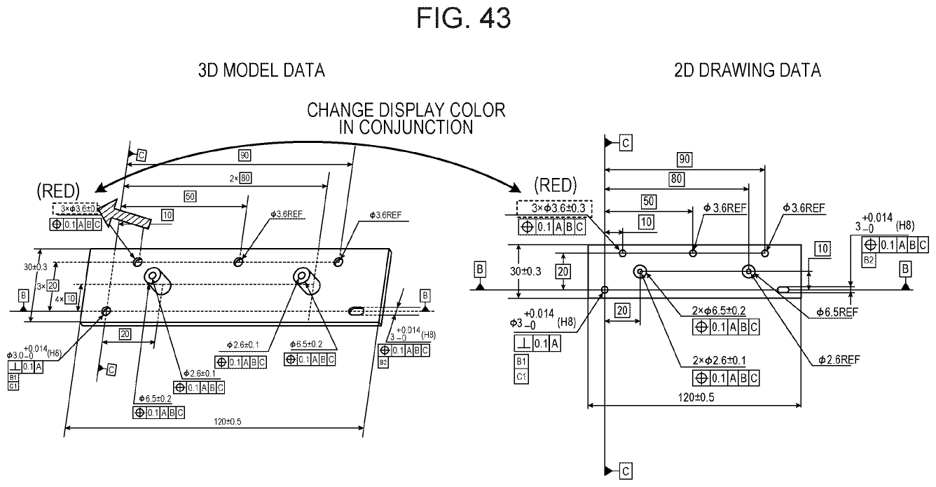

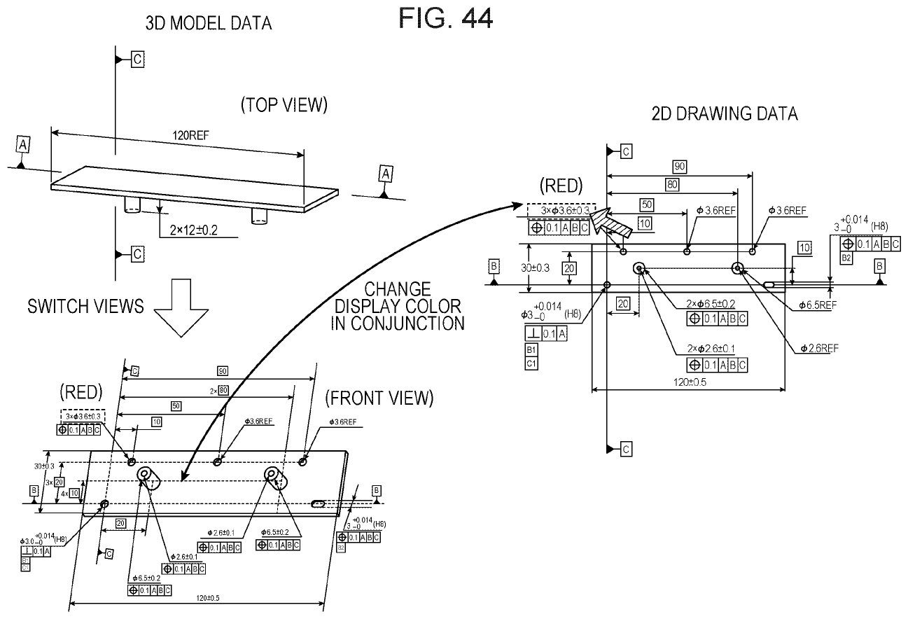

FIGS. 43 and 44 illustrate process examples in which if the PMI in one piece of data of the displayed 3D model data and the 2D drawing data is selected, the 2D drawing generator 36 modifies a display form of the corresponding PMI in the other piece of data of the 3D model data and the 2D drawing data. If the PMI in the one piece of data of the 3D model data and the 2D drawing data is selected, the 2D drawing generator 36 modifies not only the display color of the selected PMI to, for example, red, but also the display color of the corresponding PMI in the other piece of data of the 3D model data and the 2D drawing data to red.

FIG. 43 illustrates how the selection of the PMI in the 3D model data changes the display color of the PMI from black to red and the display color of the corresponding PMI in the 2D drawing data from black to red.

FIG. 44 illustrates how the selection of the PMI in the 2D drawing data changes the display color of the PMI from black to red and the display color of the corresponding PMI in the 3D model data from black to red. If the view of the PMI selected in the 2D drawing data is not displayed on the 3D model data, the display color of the PMI is changed when the view to be displayed on the 3D model is switched to the corresponding view. Referring to FIG. 44, the top view is displayed on the 3D model data when PMI is selected on the 2D drawing, and when view switching to the front view is performed, the display color of the PMI is changed.

When the one piece of data of the displayed 3D model data and the 2D drawing data is selected, the 2D drawing generator 36 may output, to the outside, not only information identifying the corresponding PMI of the other piece of data of the 3D model data and the 2D drawing data but also a combination of the 3D model data and the 2D drawing data.

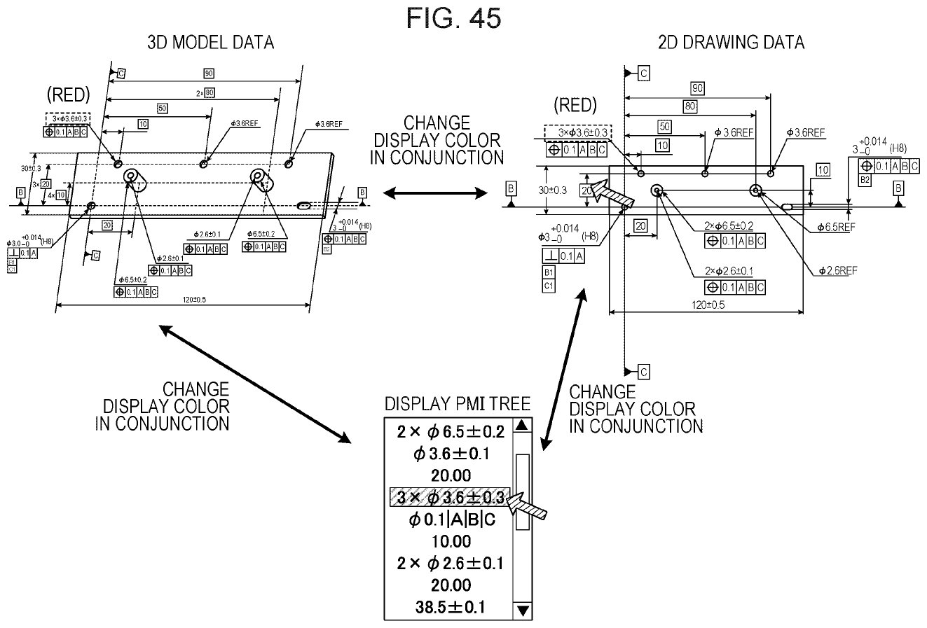

The use of the output data may switch the display form with the PMI in the 3D model data and the PMI in the 2D drawing data being operative in conjunction. Referring to FIG. 45, a PMI tree may be displayed. Selecting PMI in the PMI tree display may cause the corresponding PMI in the 3D model data or the corresponding PMI in the 2D drawing data to be in a selected state or may cause the display color to be changed.

In the embodiments above, the term “processor” refers to hardware in a broad sense. Examples of the processor include general processors (e.g., CPU: Central Processing Unit) and dedicated processors (e.g., GPU: Graphics Processing Unit, ASIC: Application Specific Integrated Circuit, FPGA: Field Programmable Gate Array, and programmable logic device).

In the embodiments above, the term “processor” is broad enough to encompass one processor or plural processors in collaboration which are located physically apart from each other but may work cooperatively. The order of operations of the processor is not limited to one described in the embodiments above, and may be changed.

The foregoing description of the exemplary embodiments of the present disclosure has been provided for the purposes of illustration and description. It is not intended to be exhaustive or to limit the disclosure to the precise forms disclosed. Obviously, many modifications and variations will be apparent to practitioners skilled in the art. The exemplary embodiments was chosen and described in order to best explain the principles of the disclosure and its practical applications, thereby enabling others skilled in the art to understand the disclosure for various embodiments and with the various modifications as are suited to the particular use contemplated. It is intended that the scope of the disclosure be defined by the following claims and their equivalents.

### APPENDIX

(((1)))

An information processing apparatus including:
a processor configured to:
   generate multiple two-dimensional (2D) projection images from three-dimensional (3D) model data that displays product manufacturing information about a shape of a product, the 2D projection images obtained through projection of the product in multiple directions; and
   generate 2D drawing data where the 2D projection images are placed, in a manner that satisfies a preset layout rule, on multiple sheet regions of a number and of a sheet size determined in accordance with the preset layout rule.
      (((2)))

In the information processing apparatus according to (((1))), the processor may be configured to generate the 2D drawing data by determining a scaling factor, a sheet size, the number of sections of each sheet, and the number of sheets in a step-by-step manner in accordance with a priority order of at least two layout rules and by placing, in accordance with the layout rules, the generated 2D projection images on the sheet regions of the determined number and the determined sheet size.

(((3)))

In the information processing apparatus according to (((1))) or (((2))), the layout rules may include a rule that the 2D projection images including the product manufacturing information about a datum target is placed on a first page.

(((4)))

In the information processing apparatus according to one of (((1))) through (((3))), the layout rules may include a rule that the 2D projection images corresponding to six basic views in an orthographic projection method are placed on a first page in accordance with a third angle projection method or a first angle projection method.

(((5)))

In the information processing apparatus according to one of (((1))) through (((4))), the layout rules may include a rule that each of the 2D projection images is placed on a sheet region having a minimum sheet size that enables each 2D projection image to be accommodated at a set scaling factor.

(((6)))

In the information processing apparatus according to one of (((1))) through (((5))), the layout rules may include a rule that each of the 2D projection images is placed such that numbers of the 2D projection images to be placed on the sheet regions of pages are equalized with respect to a predetermined range.

(((7)))

In the information processing apparatus according to one of (((1))) through (((6))), the layout rules may include a rule that a cross-sectional view representing a cross section of a 2D projection image and/or a detailed view that is an enlarged view of a portion of the 2D projection image are placed on a sheet region of a page of the 2D projection image.

(((8)))

In the information processing apparatus according to one of (((1))) through (((7))), the processor may be configured to place each of the 2D projection images by applying multiple rules included in the layout rules in accordance with a preset priority order or a priority order specified by a user.

(((9)))

In the information processing apparatus according to (((1))), the processor may be configured to place each of the 2D projection images in a scale enlarged form if a size of the product represented as a 3D model is equal to or below a predetermined threshold.

(((10)))

In the information processing apparatus according to (((1))), the processor may be configured to generate a detailed drawing that results from enlarging a portion of a region that satisfies a preset condition in each of the 2D projection images and to place the detailed drawing on the sheet region.

(((11)))

In the information processing apparatus according to (((1))), the processor may be configured to place a 2D projection image on the sheet region wherein the 2D projection image is generated directly or is generated from a detailed drawing that results from enlarging a portion of a region satisfying a preset condition in the 3D model data and that is added to the 3D model data.

(((12)))

In the information processing apparatus according to (((11))), the processor may be configured to generate the detailed drawing as the region satisfying the preset condition, wherein the region satisfying the preset condition is a region that includes a portion having a reference dimension equal or below a preset value, a region that includes a portion having a ratio of the portion to a size of the product having a reference dimension, the ratio being equal to or below a preset value, or a region that has a density of a portion having a specified reference dimension, the density being equal to or above a preset value.

(((13)))

In the information processing apparatus according to (((1))), the processor may be configured to place each of the generated 2D projection images on the sheet region such that the generated 2D projection images do not touch each other or do not touch a drawing frame that is printed as an outline frame of the 2D projection images.

(((14)))

In the information processing apparatus according to (((13))), the processor may be configured to divide the sheet region into multiple regions and place respectively the 2D projection images on the regions.

(((15)))

In the information processing apparatus according to (((13))), the processor may be configured to determine whether the 2D projection images have touched each other, by converting graphic components included in a 2D projection image described in a vector code format into image data in a raster format and performing touch determination as to whether touching has occurred in the image data of the graphic components in the raster format.

(((16)))

In the information processing apparatus according to (((15))), the processor may be configured to notify a user of an occurrence of touching of the 2D projection images or eliminate the touching by moving one of the 2D projection images determined as being in touch with each other or by reducing a whole of the 2D projection image in scale or by shortening a portion of the 2D projection images.

(((17)))

In the information processing apparatus according to (((1))), the processor may be configured to, if the 2D projection image is generated in accordance with the 3D model data, correct in advance a display setting of the product manufacturing information in the 3D model data such that the display setting of the production manufacturing information displayed in the generated 2D projection image is optimized in a 2D drawing.

(((18)))

In the information processing apparatus according to (((1))), the processor may be configured to, when the generated 2D drawing data and the 3D model data are displayed and if the product manufacturing information on a first piece of data of the 2D drawing data and the 3D model data is selected, modify a display form of the product manufacturing information on a second piece of data of the 2D drawing data and the 3D model data.

(((19)))

In the information processing apparatus according to (((1))), the processor may be configured to, if the product manufacturing information on a first piece data of the 2D drawing data and the 3D model data is selected, output to outside not only information identifying the product manufacturing information on a second piece of data of the 2D drawing data and the 3D model data but also a set of the 2D drawing data and the 3D model data.

(((20)))

A program causing a computer to execute a process, the process including:
generating multiple two-dimensional (2D) projection images from three-dimensional (3D) model data that displays product manufacturing information about a shape of a product, the 2D projection images obtained through projection of the product in multiple directions; and
generating 2D drawing data where the 2D projection images are placed, in a manner that satisfies a preset layout rule, on multiple sheet regions of a number and of a sheet size determined in accordance with the preset layout rule.

What is claimed is:

1. An information processing apparatus comprising:
a processor configured to:
generate a plurality of two-dimensional (2D) projection images from three-dimensional (3D) model data that displays product manufacturing information about a shape of a product, the 2D projection images obtained through projection of the product in a plurality of directions; and
generate 2D drawing data where the 2D projection images are placed, in a manner that satisfies a preset layout rule, on a plurality of sheet regions of a number and of a sheet size determined in accordance with the preset layout rule.

2. The information processing apparatus according to claim 1, wherein the processor is configured to generate the 2D drawing data by determining a scaling factor, a sheet size, a number of sections of each sheet, and a number of sheets in a step-by-step manner in accordance with a priority order of at least two layout rules and by placing, in accordance with the layout rules, the generated 2D projection images on the sheet regions of the determined number and the determined sheet size.

3. The information processing apparatus according to claim 1, wherein the layout rules comprise a rule that the 2D projection images including the product manufacturing information about a datum target is placed on a first page.

4. The information processing apparatus according to claim 1, wherein the layout rules comprise a rule that the 2D projection images corresponding to six basic views in an orthographic projection method are placed on a first page in accordance with a third angle projection method or a first angle projection method.

5. The information processing apparatus according to claim 1, wherein the layout rules comprise a rule that each of the 2D projection images is placed on a sheet region having a minimum sheet size that enables each 2D projection image to be accommodated at a set scaling factor.

6. The information processing apparatus according to claim 1, wherein the layout rules comprise a rule that each of the 2D projection images is placed such that numbers of the 2D projection images to be placed on the sheet regions of pages are equalized with respect to a predetermined range.

7. The information processing apparatus according to claim 1, wherein the layout rules comprise a rule that a cross-sectional view representing a cross section of a 2D projection image and/or a detailed view that is an enlarged view of a portion of the 2D projection image are placed on a sheet region of a page of the 2D projection image.

8. The information processing apparatus according to claim 1, wherein the processor is configured to place each of the 2D projection images by applying a plurality of rules included in the layout rules in accordance with a preset priority order or a priority order specified by a user.

9. The information processing apparatus according to claim 1, wherein the processor is configured to place each of the 2D projection images in a scale enlarged form if a size of the product represented as a 3D model is equal to or below a predetermined threshold.

10. The information processing apparatus according to claim 1, wherein the processor is configured to generate a detailed drawing that results from enlarging a portion of a region that satisfies a preset condition in each of the 2D projection images and to place the detailed drawing on the sheet region.

11. The information processing apparatus according to claim 1, wherein the processor is
configured to place a 2D projection image on the sheet region wherein the 2D projection image is directly generated or is generated from a detailed drawing that results from enlarging a portion of a region satisfying a preset condition in the 3D model data and that is added to the 3D model data.

12. The information processing apparatus according to claim 11, wherein the processor is configured to generate the detailed drawing as the region satisfying the preset condition, wherein the region satisfying the preset condition is a region that includes a portion having a reference dimension equal or below a preset value, a region that includes a portion having a ratio of the portion to a size of the product having a reference dimension, the ratio being equal to or below a preset value, or a region that has a density of a portion having a specified reference dimension, the density being equal to or above a preset value.

13. The information processing apparatus according to claim 1, wherein the processor is configured to place each of the generated 2D projection images on the sheet region such that the generated 2D projection images do not touch each other or do not touch a drawing frame that is printed as an outline frame of the 2D projection images.

14. The information processing apparatus according to claim 13, wherein the processor is configured to divide the sheet region into a plurality of regions and place respectively the 2D projection images on the regions.

15. The information processing apparatus according to claim 13, wherein the processor is configured to determine whether the 2D projection images have touched each other, by converting graphic components included in a 2D projection image described in a vector code format into image data in a raster format and performing touch determination as to whether touching has occurred in the image data of the graphic components in the raster format.

16. The information processing apparatus according to claim 15, wherein the processor is configured to notify a user of an occurrence of touching of the 2D projection images or eliminate the touching by moving one of the 2D projection images determined as being in touch with each other or by reducing a whole of the 2D projection images in scale or by shortening a portion of the 2D projection images.

17. The information processing apparatus according to claim 1, wherein the processor is configured to, if the 2D projection image is generated in accordance with the 3D model data, correct in advance a display setting of the product manufacturing information in the 3D model data such that the display setting of the production manufacturing information displayed in the generated 2D projection image is optimized in a 2D drawing.

18. The information processing apparatus according to claim 1, wherein the processor is configured to, when the generated 2D drawing data and the 3D model data are displayed and if the product manufacturing information on a first piece of data of the 2D drawing data and the 3D model data is selected, modify a display form of the product manufacturing information on a second piece of data of the 2D drawing data and the 3D model data.

19. The information processing apparatus according to claim 1, wherein the processor is configured to, if the product manufacturing information on a first piece data of the 2D drawing data and the 3D model data is selected, output to outside not only information identifying the product manufacturing information on a second piece of data of the 2D drawing data and the 3D model data but also a set of the 2D drawing data and the 3D model data.

20. A non-transitory computer readable medium storing a program causing a computer to execute a process, the process comprising:
generating a plurality of two-dimensional (2D) projection images from three-dimensional (3D) model data that displays product manufacturing information about a shape of a product, the 2D projection images obtained through projection of the product in multiple directions; and
generating 2D drawing data where the 2D projection images are placed, in a manner that satisfies a preset layout rule, on a plurality of sheet regions of a number and of a sheet size determined in accordance with the preset layout rule.
